(19) United States
(12) Patent Application Publication
(10) Pub. No.: US 2024/0397772 A1
(43) Pub. Date: Nov. 28, 2024

(54) DISPLAY DEVICE AND METHOD FOR MANUFACTURING THE DISPLAY DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Ryota HODO, Atsugi (JP); Yuichi YANAGISAWA, Atsugi (JP)

(21) Appl. No.: 18/695,118

(22) PCT Filed: Sep. 26, 2022
(86) PCT No.: PCT/IB2022/059070

§ 371 Date: Mar. 25, 2024

(30) Foreign Application Priority Data
Oct. 7, 2021 (JP) 2021-165733

(51) Int. Cl. H10K 59/131; H10K 50/19; H10K 59/12; H10K 59/38

(52) U.S. Cl. CPC H10K 59/131; H10K 50/19; H10K 59/1201; H10K 59/38

(57) ABSTRACT

A display device with high display quality is provided. The display device includes a first light-emitting device, a second light-emitting device, and an insulating layer. The first light-emitting device includes a first pixel electrode, a first EL layer, and a common electrode. The second light-emitting device includes a second pixel electrode, a second EL layer, and the common electrode. The insulating layer includes an opening, and includes a first surface in contact with a side surface of the first pixel electrode, a second surface facing the first surface, and a third surface in contact with a bottom surface of the first EL layer. The insulating layer includes a region where the third surface and the top surface of the first pixel electrode are level or substantially level with each other. In a cross-sectional view, an angle formed between the second surface and the third surface is greater than or equal to 80° and less than or equal to 110°. The first EL layer contains the same material as the second EL layer. The first EL layer is separated from the second EL layer.

### TECHNICAL FIELD

One embodiment of the present invention relates to a display device, a display module, and an electronic device. One embodiment of the present invention relates to a method for manufacturing a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Display devices have been expected to be applied to a variety of uses. Usage examples of large-sized display devices include a television device for home use (also referred to as TV or television receiver), digital signage, and a PID (Public Information Display). In addition, a smartphone and a tablet terminal each including a touch panel, and the like, are being developed as portable information terminals.

In recent years, display devices applicable to virtual reality (VR), augmented reality (AR), substitutional reality (SR), or mixed reality (MR) have been desired. VR, AR, SR, and MR are collectively referred to as extended reality (xR). Display devices for xR have been expected to have higher resolution and higher color reproducibility so that realistic feeling and the sense of immersion can be enhanced.

Light-emitting apparatuses including light-emitting devices (also referred to as light-emitting elements) have been developed as display devices, for example. Light-emitting devices utilizing an electroluminescence (hereinafter referred to as EL) phenomenon (also referred to as EL devices or EL elements) have features such as ease of reduction in thickness and weight, high-speed response to input signals, and driving with a constant DC voltage power source, and have been used in display devices.

Patent Document 1 discloses a display device using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a display device with high display quality. An object of one embodiment of the present invention is to provide a high-resolution display device. An object of one embodiment of the present invention is to provide a high-definition display device. An object of one embodiment of the present invention is to provide a highly reliable display device.

An object of one embodiment of the present invention is to provide a method for manufacturing a high-resolution display device. An object of one embodiment of the present invention is to provide a method for manufacturing a high-definition display device. An object of one embodiment of the present invention is to provide a method for manufacturing a highly reliable display device. An object of one embodiment of the present invention is to provide a method for manufacturing a display device with high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device including a first light-emitting device, a second light-emitting device, and an insulating layer. The first light-emitting device includes a first pixel electrode, a first EL layer over the first pixel electrode, and a common electrode over the first EL layer. The second light-emitting device includes a second pixel electrode, a second EL layer over the second pixel electrode, and the common electrode over the second EL layer. The insulating layer includes an opening. The insulating layer includes a first surface in contact with a side surface of the first pixel electrode, a second surface facing the first surface, a third surface in contact with a bottom surface of the first EL layer, a fourth surface in contact with a side surface of the second pixel electrode, a fifth surface facing the fourth surface, and a sixth surface in contact with a bottom surface of the second EL layer. The insulating layer includes a region where the third surface, the sixth surface, a top surface of the first pixel electrode, and a top surface of the second pixel electrode are level or substantially level with each other. In a cross-sectional view, an angle formed between the second surface and the third surface is greater than or equal to 80° and less than or equal to 110°. The first EL layer contains the same material as the second EL layer. The first EL layer is separated from the second EL layer.

In the above-described display device, the ratio of the depth of the opening to the thickness of the first EL layer is preferably higher than or equal to 0.5 and lower than or equal to 10.0.

In the above-described display device, the width of the opening is preferably greater than or equal to 50 nm and less than or equal to 500 nm.

The above-described display device preferably includes a first coloring layer and a second coloring layer. The first coloring layer preferably includes a region overlapping with the first light-emitting device. The second coloring layer preferably includes a region overlapping with the second light-emitting device. Light transmitted through the second coloring layer preferably has a shorter wavelength than that of light transmitted through the first coloring layer.

In the above-described display device preferably includes a first conductive layer and a second conductive layer. The first conductive layer and the second conductive layer each preferably transmit visible light. The first conductive layer is preferably interposed between the first pixel electrode and the first EL layer. The second conductive layer is preferably interposed between the second pixel electrode and the second EL layer. The thickness of the second conductive layer is preferably smaller than that of the first conductive layer.

In the above-described display device, a side surface of the first conductive layer is preferably aligned or substantially aligned with the second surface. A side surface of the second conductive layer is preferably aligned or substantially aligned with the fifth surface.

One embodiment of the present invention is a method for manufacturing a display device including a step of forming a first pixel electrode and a second pixel electrode; a step of forming an insulating film covering top surfaces and side surfaces of the first pixel electrode and the second pixel electrode; a step of forming an insulating layer which is level or substantially level with the top surface of the first pixel electrode and the top surface of the second pixel electrode by removing part of the insulating film; a step of forming an opening in the insulating layer; a step of forming a first EL layer over the first pixel electrode and forming a second EL layer which is separated from the first EL layer over the second pixel electrode; and a step of forming a common electrode over the first EL layer and the second EL layer. The insulating layer includes a first surface in contact with the side surface of the first pixel electrode, a second surface facing the first surface, and a third surface in contact with a bottom surface of the first EL layer. The insulating layer includes a region where the third surface is level or substantially level with the top surface of the first pixel electrode. In a cross-sectional view, an angle formed between the second surface and the third surface is greater than or equal to 80° and less than or equal to 110°. The first EL layer contains the same material as the second EL layer.

### Effect of the Invention

With one embodiment of the present invention, a display device with high display quality can be provided. With one embodiment of the present invention, a high-resolution display device can be provided. With one embodiment of the present invention, a high-definition display device can be provided. With one embodiment of the present invention, a highly reliable display device can be provided.

With one embodiment of the present invention, a method for manufacturing a high-resolution display device can be provided. With one embodiment of the present invention, a method for manufacturing a high-definition display device can be provided. With one embodiment of the present invention, a method for manufacturing a highly reliable display device can be provided. With one embodiment of the present invention, a method for manufacturing a display device with high yield can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display device. FIG. 1B is a cross-sectional view illustrating the example of the display device.

FIG. 2 is a cross-sectional view illustrating an example of a display device.

FIG. 3A and FIG. 3B are cross-sectional views illustrating an example of a display device.

FIG. 4A and FIG. 4B are cross-sectional views illustrating an example of a display device.

FIG. 5A and FIG. 5B are cross-sectional views illustrating an example of a display device.

FIG. 6 is a cross-sectional view illustrating an example of a display device.

FIG. 7A and FIG. 7B are cross-sectional views illustrating an example of a display device.

FIG. 8A and FIG. 8B are cross-sectional views illustrating an example of a display device.

FIG. 9A and FIG. 9B are cross-sectional views illustrating an example of a display device.

FIG. 10A to FIG. 10C are cross-sectional views illustrating examples of a display device.

FIG. 11 is a cross-sectional view illustrating an example of a display device.

FIG. 12A to FIG. 12E are cross-sectional views illustrating an example of a method for manufacturing a display device.

FIG. 13A to FIG. 13C are cross-sectional views illustrating an example of a method for manufacturing a display device.

FIG. 14A to FIG. 14C are cross-sectional views illustrating an example of a method for manufacturing a display device.

FIG. 15A to FIG. 15G are diagrams illustrating examples of pixels.

FIG. 16A to FIG. 16K are diagrams illustrating examples of a pixel.

FIG. 17A and FIG. 17B are perspective views illustrating an example of a display device.

FIG. 18 is a cross-sectional view illustrating an example of a display device.

FIG. 19 is a cross-sectional view illustrating an example of a display device.

FIG. 20 is a cross-sectional view illustrating an example of a display device.

FIG. 21 is a cross-sectional view illustrating an example of a display device.

FIG. 22 is a cross-sectional view illustrating an example of a display device.

FIG. 23 is a cross-sectional view illustrating an example of a display device.

FIG. 24 is a perspective view illustrating an example of a display device.

FIG. 25A is a cross-sectional view illustrating an example of a display device. FIG. 25B and FIG. 25C are cross-sectional views illustrating examples of transistors.

FIG. 26 is a cross-sectional view illustrating an example of a display device.

FIG. 27A to FIG. 27F are diagrams illustrating structure examples of a light-emitting device.

FIG. 28A to FIG. 28C are diagrams illustrating structure examples of a light-emitting device.

FIG. 29A to FIG. 29D are diagrams illustrating examples of electronic devices.

FIG. 30A to FIG. 30F are diagrams illustrating examples of electronic devices.

FIG. 31A to FIG. 31G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, or the like of each component illustrated in drawings does not represent the actual position, size, range, or the like in some cases for easy understanding.

Therefore, the disclosed invention is not necessarily limited to the position, size, range, or the like disclosed in the drawings.

Note that the term “film” and the term “layer” can be interchanged with each other depending on the case or the circumstances. For example, the term “conductive layer” can be replaced with the term “conductive film”. As another example, the term “insulating film” can be replaced with the term “insulating layer”.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM may be referred to as a device having an MML (metal maskless) structure.

In this specification and the like, a structure in which light-emitting layers of light-emitting devices having different emission wavelengths are separately formed is sometimes referred to as an SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°. Note that the side surface of the structure and the substrate surface are not necessarily completely flat and may be substantially flat with a slight curvature or substantially flat with slight unevenness.

### Embodiment 1

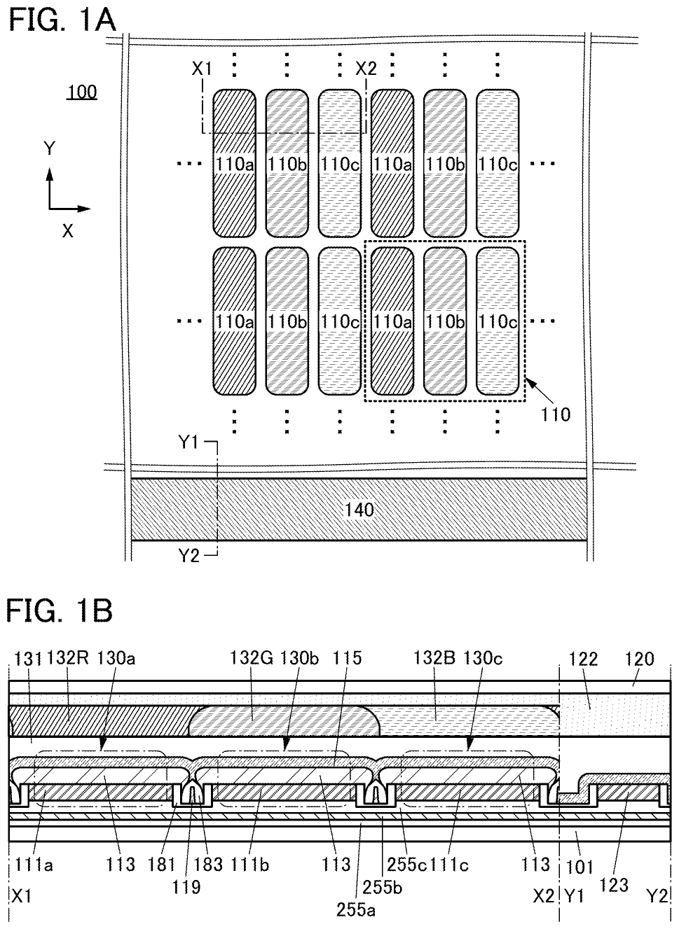

In this embodiment, a display device of one embodiment of the present invention is described with reference to FIG. 1 to FIG. 14.

The display device of one embodiment of the present invention includes a plurality of pixels, and each pixel includes a plurality of subpixels. In the display device of one embodiment of the present invention, each subpixel includes a light-emitting device and a coloring layer. The light-emitting devices include EL layers containing the same material. The coloring layer is provided in a region overlapping with the light-emitting device. When coloring layers which transmit visible light of different colors are provided in subpixels, the display device can perform full-color display.

In the case of using light-emitting devices including EL layers having the same structure, a layer other than a pixel electrode included in the light-emitting device (e.g., a light-emitting layer) can be common between a plurality of subpixels. Thus, the plurality of subpixels can share a continuous film. However, some of the layers included in the light-emitting device have relatively high conductivity. When the plurality of subpixels share a continuous film with high conductivity, leakage current might be generated between the subpixels. Particularly when the increase in resolution or aperture ratio of a display device reduces the distance between subpixels, the leakage current might become too large to ignore and cause a decrease in display quality of the display device, for example.

The display device of one embodiment of the present invention includes an island-shaped EL layer for each light-emitting device. When the EL layers are separated between the light-emitting devices, generation of crosstalk between adjacent subpixels can be inhibited. This enables the display device to achieve both high resolution and high display quality.

In this specification and the like, the term “island shape” refers to a state where two or more layers formed using the same material in the same step are physically separated from each other. For example, the term “island-shaped EL layer” refers to a state where the EL layer and its adjacent EL layer are physically separated from each other.

For example, an island-shaped EL layer can be formed by a vacuum evaporation method using a metal mask. However, this method causes a deviation from the designed shape and position of an island-shaped EL layer due to various influences such as the low accuracy of the metal mask, the positional deviation between the metal mask and a substrate, a warp of the metal mask, and the vapor-scattering-induced expansion of the outline of the deposited film; accordingly, it is difficult to increase the resolution and the aperture ratio of the display device. In addition, the outline of the layer might blur during evaporation, so that the thickness of an end portion might be reduced. That is, the thickness of the island-shaped EL layer formed using a metal mask may vary.

In the case of manufacturing a display device with a large size, high definition, or high resolution, the manufacturing yield might be reduced because of low dimensional accuracy of the metal mask and deformation due to heat or the like.

Thus, when the display device of one embodiment of the present invention is manufactured, an island-shaped EL layer is formed without using a shadow mask such as a metal mask. Specifically, an insulating layer is provided between pixel electrodes, an opening is formed in the insulating layer, and then an EL layer is formed across the plurality of pixel electrodes. When the EL layer is formed, the EL layer is divided into island shapes by a step formed by the opening, and one island-shaped EL layer is formed for one pixel electrode. That is, an island-shaped EL layer can be formed for each subpixel.

When the EL layer is formed into an island shape, functional layers other than a light-emitting layer (e.g., a carrier-injection layer, a carrier-transport layer, and a carrier-blocking layer, more specifically, a hole-injection layer, a hole-transport layer, and an electron-blocking layer) are also formed into an island shape. Processing the functional layers into an island shape can reduce leakage current (sometimes referred to as horizontal-direction leakage current, horizontal leakage current, or lateral leakage current) that might be generated between adjacent subpixels. For example, in the case where the hole-injection layer is shared by adjacent subpixels, horizontal leakage current might be generated due to the hole-injection layer. Meanwhile, in the display device of one embodiment of the present invention, the hole-injection layer can be processed into an island shape; hence, horizontal leakage current between adjacent subpixels is not substantially generated or horizontal leakage current can be extremely small.

Here, when steps performed after formation of the EL layer are performed at temperature higher than the upper temperature limit of the EL layer, deterioration of the EL layer proceeds, which might result in a decrease in the emission efficiency and reliability of the light-emitting device.

Thus, in one embodiment of the present invention, the upper temperature limits of compounds contained in the light-emitting device is preferably higher than or equal to 100° C. and lower than or equal to 180° C. or higher than or equal to 120° C. and lower than or equal to 180° C., further preferably higher than or equal to 140° C. and lower than or equal to 180° C.

Examples of indicators of the upper temperature limit include the glass transition point (Tg), the softening point, the melting point, the thermal decomposition temperature, and the 5% weight loss temperature. For example, as an indicator of the upper temperature limit of a layer included in the EL layer, a glass transition point of a material contained in the layer can be used. In the case where the layer is a mixed layer formed of a plurality of materials, a glass transition point of a material contained in the highest proportion can be used, for example. Alternatively, the lowest temperature among the glass transition points of the materials may be used. In particular, the upper temperature limits of functional layers provided over the light-emitting layer are preferably high. It is further preferable that the upper temperature limit of the functional layer provided over and in contact with the light-emitting layer be high. When the functional layer has high heat resistance, the light-emitting layer can be effectively protected and damage to the light-emitting layer can be reduced.

In addition, it is particularly preferable that the upper temperature limit of the light-emitting layer be high. In this case, the light-emitting layer can be inhibited from being damaged by heating and being decreased in emission efficiency and lifetime.

Increasing the upper temperature limit of the light-emitting device can improve the reliability of the light-emitting device. Furthermore, the allowable temperature range in the manufacturing process of the display device can be widened, thereby improving the manufacturing yield and the reliability.

In this embodiment, the display device of one embodiment of the present invention will be described.

### Structure Example 1

FIG. 1A is a top view illustrating a display device 100 of one embodiment of the present invention. The display device 100 includes a display portion in which a plurality of pixels 110 are arranged in a matrix and a connection portion 140 outside the display portion. The pixels 110 each include a plurality of subpixels. FIG. 1A illustrates the pixels 110 in two rows and two columns. As the structure where the pixels 110 each include three subpixels (a subpixel 110a, a subpixel 110b, and a subpixel 110c), the subpixels in two rows and six columns are illustrated. The connection portion 140 can also be referred to as a cathode contact portion.

Each of the subpixels includes a light-emitting device. The plan view shape (hereinafter also referred to as a top surface shape) of the subpixel illustrated in FIG. 1A corresponds to the top surface shape of a light-emitting region of the light-emitting device. Examples of the top surface shape of the subpixel include polygons such as a triangle, a quadrangle (including a rectangle and a square), and a pentagon; polygons with rounded corners; an ellipse; and a circle.

The subpixels each include a pixel circuit that has a function of controlling the light-emitting device. The pixel circuits are not necessarily placed in the ranges of the subpixels illustrated in FIG. 1A and may be placed outside the subpixels. For example, transistors included in a pixel circuit of the subpixel 110a may be positioned within the range of the subpixel 110b illustrated in FIG. 1A, or some or all of the transistors may be positioned outside the range of the subpixel 110a.

Although the subpixel 110a, the subpixel 110b, and the subpixel 110c have the same aperture ratio (also referred to as the same size or the same size of light-emitting regions) or substantially the same aperture ratios in FIG. 1A, one embodiment of the present invention is not limited thereto. The aperture ratio of each of the subpixel 110a, the subpixel 110b, and the subpixel 110c can be determined as appropriate. The subpixel 110a, the subpixel 110b, and the subpixel 110c may have different aperture ratios, or two or more of the subpixel 110a, the subpixel 110b, and the subpixel 110c may have the same or substantially the same aperture ratio.

The pixel 110 illustrated in FIG. 1A employs stripe arrangement. The pixel 110 illustrated in FIG. 1A is composed of three subpixels: the subpixel 110a, the subpixel 110b, and the subpixel 110c. The subpixel 110a, the subpixel 110b, and the subpixel 110c exhibit light of different colors. The subpixel 110a, the subpixel 110b, and the subpixel 110c can be subpixels of three colors of red (R), green (G), and blue (B) or subpixels of three colors of yellow (Y), cyan (C), and magenta (M), for example. The number of colors of subpixels is not limited to three and may be four or more. As the subpixels of four colors, subpixels of four colors of R, G, B, and white (W), subpixels of four colors of R, G, B, and Y, or four subpixels of R, G, B, and infrared light (IR) can be given, for example.

In this specification and the like, the row direction is referred to as X direction and the column direction is referred to as Y direction, in some cases. The X direction and the Y direction intersect with each other and are, for example, orthogonal to each other (see FIG. 1A). FIG. 1A illustrates an example in which subpixels of different colors are arranged in the X direction and subpixels of the same color are arranged in the Y direction.

Although the top view in FIG. 1A illustrates an example in which the connection portion 140 is positioned on one side of the display portion, the position of the connection portion is not particularly limited. The connection portion 140 is provided in at least one portion of the display portion and may be provided so as to surround the four sides of the display portion in the top view. The top surface shape of the connection portion 140 is not particularly limited and can be a belt-like shape, an L shape, a U shape, a frame-like shape, or the like. The number of the connection portions 140 can be one or more.

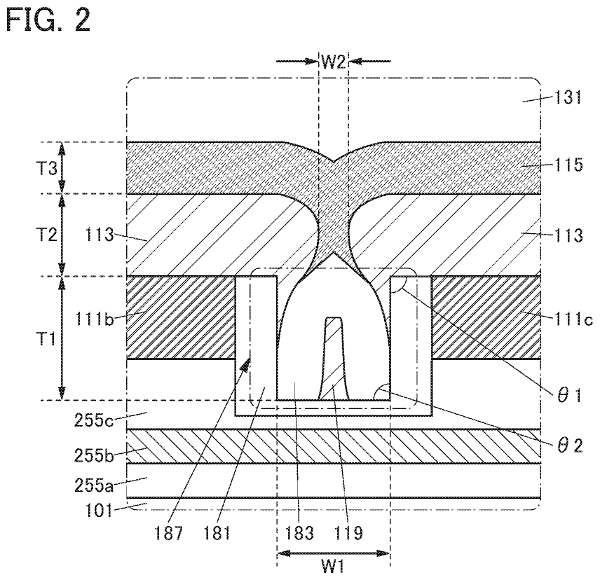

FIG. 1B is a cross-sectional view along dashed-dotted line X1-X2 and dashed-dotted line Y1-Y2 in FIG. 1A. An enlarged view of part of the cross-sectional view illustrated in FIG. 1B is illustrated in FIG. 2. Here, a structure in which red light is emitted from the subpixel 110a, green light is emitted from the subpixel 110b, and blue light is emitted from the subpixel 110c is described as an example.

The subpixel 110a includes a light-emitting device 130a and a coloring layer 132R transmitting red light. Thus, light emitted by the light-emitting device 130a is extracted as red light to the outside of the display device through the coloring layer 132R.

Similarly, the subpixel 110b includes a light-emitting device 130b and a coloring layer 132G transmitting green light. Thus, light emitted by the light-emitting device 130b is extracted as green light to the outside of the display device through the coloring layer 132G.

The subpixel 110c includes a light-emitting device 130c and a coloring layer 132B that transmits blue light. Thus, light emitted by the light-emitting device 130c is extracted as blue light to the outside of the display device through the coloring layer 132B.

Note that in the case of describing matters common to the light-emitting device 130a, the light-emitting device 130b, and the light-emitting device 130c, these light-emitting devices are sometimes referred to as a light-emitting device 130 by omitting the alphabets that distinguish them from each other. Similarly, in the description of matters common to components that are distinguished from each other using alphabets, such as the coloring layer 132R, the coloring layer 132G, and the coloring layer 132B, reference numerals without alphabets are sometimes used.

As illustrated in FIG. 1B, the display device 100 includes insulating layers over a layer 101, the light-emitting device 130a, the light-emitting device 130b, and the light-emitting device 130c over the insulating layers, and a protective layer 131 provided to cover these light-emitting devices 130. The coloring layer 132R, the coloring layer 132G, and the coloring layer 132B are provided over the protective layer 131, and a substrate 120 is attached onto the coloring layers with a resin layer 122. An insulating layer 181 is provided between the adjacent light-emitting devices 130.

In the case of providing a subpixel that emits white light, a structure where a coloring layer that transmits white light is provided or a structure where a coloring layer is not provided is employed.

The layer 101 preferably includes a pixel circuit having a function of controlling the light-emitting device 130. The pixel circuit can include a transistor, a capacitor, and a wiring, for example. Note that the layer 101 may include one or both of a gate line driver circuit (a gate driver) and a source line driver circuit (a source driver) in addition to the pixel circuit. Furthermore, one or both of an arithmetic circuit and a memory circuit may be included.

The layer 101 can have a structure where a pixel circuit is provided over a semiconductor substrate or an insulating substrate. As the semiconductor substrate, a single crystal semiconductor substrate or a polycrystalline semiconductor substrate using silicon or silicon carbide as a material, a compound semiconductor substrate of silicon germanium or the like, or an SOI substrate can be used. As the insulating substrate, a glass substrate, a quartz substrate, a sapphire substrate, a ceramic substrate, or an organic resin substrate can be used. Note that the shape of the semiconductor substrate and the insulating substrate may be circular or square. As the semiconductor substrate and the insulating substrate, a substrate having at least heat resistance high enough to withstand heat treatment performed later can be used.

The layer 101 can have a stacked-layer structure of a substrate provided with a plurality of transistors and an insulating layer covering these transistors, for example. The insulating layer over the transistors may have a single-layer structure or a stacked-layer structure. In FIG. 1B, the insulating layer 255a, the insulating layer 255b over the insulating layer 255a, and the insulating layer 255c over the insulating layer 255b are illustrated as the insulating layers over the transistors. These insulating layers may have a depressed portion between adjacent light-emitting devices. In the example illustrated in FIG. 1B and the like, the insulating layer 255c is provided with a depressed portion. The insulating layer 255c does not necessarily include a depressed portion between adjacent light-emitting devices. Note that the insulating layers (the insulating layer 255a to the insulating layer 255c) over the transistors can be regarded as part of the layer 101 including transistors.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. More specifically, it is preferable that a silicon oxide film be used as the insulating layer 255a and the insulating layer 255c and a silicon nitride film be used as the insulating layer 255b. The insulating layer 255b preferably has a function of an etching protective film.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

As the light-emitting device 130, an OLED (Organic Light Emitting Diode) or a QLED (Quantum-dot Light Emitting Diode) is preferably used, for example. As a light-emitting substance contained in the light-emitting device 130, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given, for example. As a light-emitting substance contained in an EL element, not only organic compounds but also inorganic compounds (e.g., quantum dot materials) can be used. An LED (Light Emitting Diode) such as a micro-LED can also be used as the light-emitting device 130.

The emission color of the light-emitting device 130 can be infrared, red, green, blue, cyan, magenta, yellow, white, or the like. When the light-emitting device 130 has a microcavity structure, the color purity can be increased.

The display device of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

A conductive film that transmits visible light can be used for one of a pair of electrodes of the light-emitting device 130 through which light is extracted, and a conductive film that reflects visible light can be used for the other of the pair of electrodes through which light is not extracted. A conductive film that transmits visible light may be used also for the electrode through which light is not extracted. In that case, a conductive film that transmits visible light is preferably provided between a conductive film that reflects visible light and the EL layer.

One of the pair of electrodes included in the light-emitting device 130 functions as an anode, and the other electrode functions as a cathode. The case where the pixel electrode functions as an anode and the common electrode functions as a cathode is described below as an example in some cases.

The light-emitting device 130a includes a pixel electrode 111a over the insulating layer 255c, an island-shaped EL layer 113 over the pixel electrode 111a, and a common electrode 115 over the EL layer 113. The light-emitting device 130b includes a pixel electrode 111b over the insulating layer 255c, the island-shaped EL layer 113 over the pixel electrode 111b, and the common electrode 115 over the EL layer 113. The light-emitting device 130c includes a pixel electrode 111c over the insulating layer 255c, the EL layer 113 over the pixel electrode 111c, and the common electrode 115 over the EL layer 113.

The display device of one embodiment of the present invention includes the island-shaped EL layer 113 provided for each of the light-emitting devices 130. Specifically, the light-emitting device 130a, the light-emitting device 130b, and the light-emitting device 130c each include the EL layer 113, and the EL layers 113 do not include overlap regions and are separated. Providing the island-shaped EL layer 113 for each of the light-emitting devices 130 can inhibit leakage current between the adjacent light-emitting devices 130. Thus, it is possible to prevent crosstalk due to unintended light emission, so that a display device with extremely high contrast can be achieved. In particular, a display device having high current efficiency at low luminance can be achieved.

The EL layers 113 can be formed using the same material in the same step. When the light-emitting device 130a, the light-emitting device 130b, and the light-emitting device 130c include EL layers with the same structure, the steps of manufacturing the display device can be reduced, which can reduce the manufacturing cost and increase the manufacturing yield.

As illustrated in FIG. 2, the insulating layer 181 provided between the adjacent light-emitting devices 130 includes a region in contact with the side surfaces of the pixel electrode 111a, the pixel electrode 111b, and the pixel electrode 111c and the top surface of the insulating layer 255c. Since the side surfaces of the pixel electrode 111a, the pixel electrode 111b, and the pixel electrode 111c are covered with the insulating layer 181, the pixel electrode 111a, the pixel electrode 111b, and the pixel electrode 111c can be inhibited from being in contact with the common electrode 115, which can inhibit a short circuit of the light-emitting device 130. Thus, the reliability of the light-emitting device 130 can be increased. Furthermore, when the side surfaces of the pixel electrode 111a, the pixel electrode 111b, and the pixel electrode 111c are covered with the insulating layer 181, impurities (typically, water and oxygen) can be inhibited from diffusing into the light-emitting device 130 through the pixel electrode 111a, the pixel electrode 111b, and the pixel electrode 111c.

Although a plurality of cross sections of the insulating layer 181 are illustrated in FIG. 1B, the insulating layer 181 is a continuous layer in a top view. In other words, the display device 100 can have a structure including one insulating layer 181, for example. Note that the display device 100 may include a plurality of insulating layers 181 which are separated from each other.

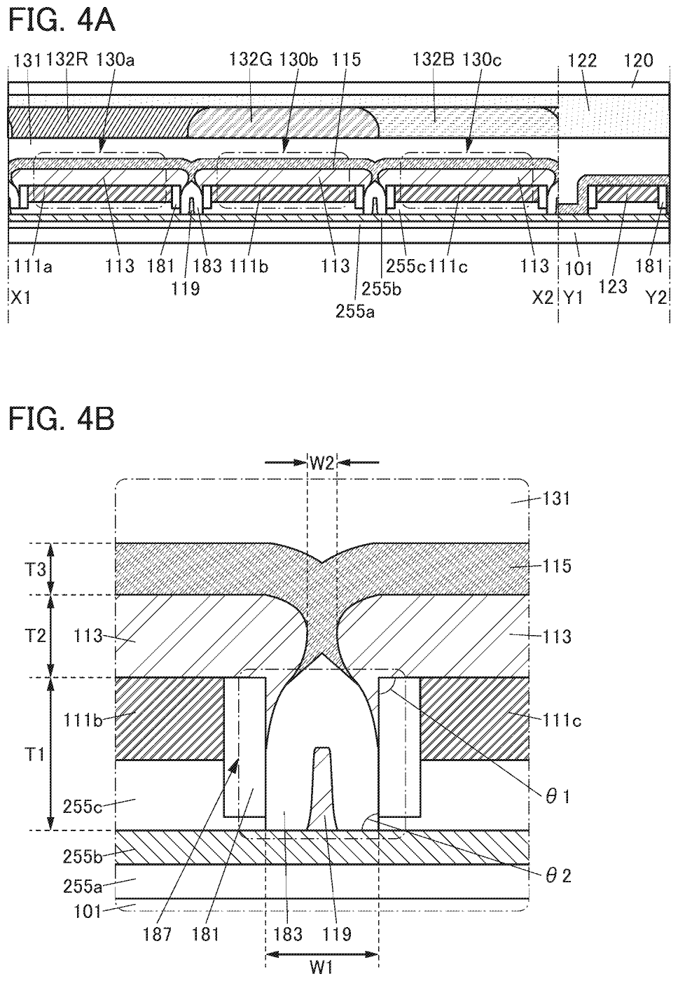

The top surface of the insulating layer 181 is level or substantially level with the top surfaces of the pixel electrode 111a, the pixel electrode 111b, and the pixel electrode 111c. The EL layer 113 is provided to cover the top surfaces of the pixel electrode 111a, the pixel electrode 111b, and the pixel electrode 111c and the top surface of the insulating layer 181. The insulating layer 181 includes an opening 187. Note that as illustrated in FIG. 1B, FIG. 2, and the like, the opening 187 has a depressed shape in the cross-sectional view. As illustrated in FIG. 4B and the like, a layer other than the insulating layer 181 (e.g., the insulating layer 255b) may be exposed in the opening 187. In the opening 187, the EL layer 113 may include a region in contact with a side surface of the insulating layer 181.

The display device of one embodiment of the present invention includes a region where the EL layer 113 is not formed on the top surfaces of the pixel electrode 111a, the pixel electrode 111b, and the pixel electrode 111c, which are the formation surface of the EL layer 113, and the top and side surfaces of the insulating layer 181. The region can be referred to as a disconnection region. FIG. 2 illustrates a structure in which a region where the EL layer 113 is not formed (disconnection region) is provided in part of the side surface and part of the top surface of the insulating layer 181. At the time of forming the EL layer 113, the formation surface of the EL layer 113 has a step generated by the opening 187. The coverage with the EL layer 113 is reduced by the step, so that a disconnection region of the EL layer 113 can be provided.

The shape of the insulating layer 181 is described using, as an example, a region between the pixel electrode 111b and the pixel electrode 111c illustrated in FIG. 2. In the region between the pixel electrode 111b and the pixel electrode 111c, the insulating layer 181 includes a first surface in contact with the side surface of the pixel electrode 111b, a second surface facing the first surface, and a third surface in contact with the bottom surface of the EL layer 113 over the pixel electrode 111b. The insulating layer 181 also includes a fourth surface in contact with the side surface of the pixel electrode 111c, a fifth surface facing the fourth surface, and a sixth surface in contact with the bottom surface of the EL layer 113 over the pixel electrode 111c. The display device of one embodiment of the present invention includes a region where the third surface, the sixth surface, the top surface of the pixel electrode 111b, and the top surface of the pixel electrode 111c are level or substantially level with each other. Note that although the insulating layer 181 positioned between the pixel electrode 111b and the pixel electrode 111c is described here, the same applies to the insulating layers 181 positioned between the other pixel electrodes 111. For example, the above description can be referred to for the insulating layer 181 positioned between the pixel electrode 111a and the pixel electrode 111b.

Note that the second surface and the fifth surface may be referred to as side surfaces of the opening 187.

In the upper portion of the opening 187, an angle θ1 formed between the side surface of the opening 187 and the top surface of the insulating layer 181 is preferably 90° or substantially 90°. The angle θ1 can be regarded as an angle formed between the side surface and the top surface of the insulating layer 181 in the upper portion of the opening 187. When the angle θ1 is large, coverage with the EL layer 113 at the time of the formation is increased; therefore, a disconnection region of the EL layer 113 might not be provided. Meanwhile, when the angle θ1 is small, the width of the insulating layer 181 in a region overlapping with the side surfaces of the pixel electrode 111a, the pixel electrode 111b, and the pixel electrode 111c might be narrowed and the side surfaces of the pixel electrode 111a, the pixel electrode 111b, and the pixel electrode 111c might be exposed. The angle θ1 is preferably greater than or equal to 80° and less than or equal to 110°, further preferably greater than or equal to 80° and less than or equal to 100°, still further preferably greater than or equal to 85° and less than or equal to 100°, yet still further preferably greater than or equal to 85° and less than or equal to 95°. When the angle θ1 is within the above range, the disconnection region of the EL layer 113 can be provided and the side surfaces of the pixel electrode 111a, the pixel electrode 111b, and the pixel electrode 111c can be inhibited from being exposed. The angle θ1 can be regarded as an angle formed between the second surface and the third surface or an angle formed between the fifth surface and the sixth surface. In FIG. 2 and the like, the angle θ1 formed between the second surface and the third surface is illustrated as a typical example.

In the bottom portion of the opening 187, an angle θ2 formed between the side surface of the opening 187 and the top surface of the insulating layer 181 is preferably 90° or substantially 90°. The angle θ2 can also be regarded as an angle formed between the side surface and the top surface of the insulating layer 181 in the bottom portion of the opening 187. When the angle θ2 is large, coverage with the EL layer 113 at the time of the formation is increased; therefore, a disconnection region of the EL layer 113 might not be provided. Meanwhile, when the angle θ2 is small, the width of the insulating layer 181 in a region overlapping with the side surfaces of the pixel electrode 111a, the pixel electrode 111b, and the pixel electrode 111c might be narrowed and the side surfaces of the pixel electrode 111a, the pixel electrode 111b, and the pixel electrode 111c might be exposed. The angle θ2 is preferably greater than or equal to 80° and less than or equal to 110°, further preferably greater than or equal to 80° and less than or equal to 100°, still further preferably greater than or equal to 85° and less than or equal to 100°, yet still further preferably greater than or equal to 85° and less than or equal to 95°. When the angle θ2 is within the above range, the disconnection region of the EL layer 113 can be provided and the side surfaces of the pixel electrode 111a, the pixel electrode 111b, and the pixel electrode 111c can be inhibited from being exposed.

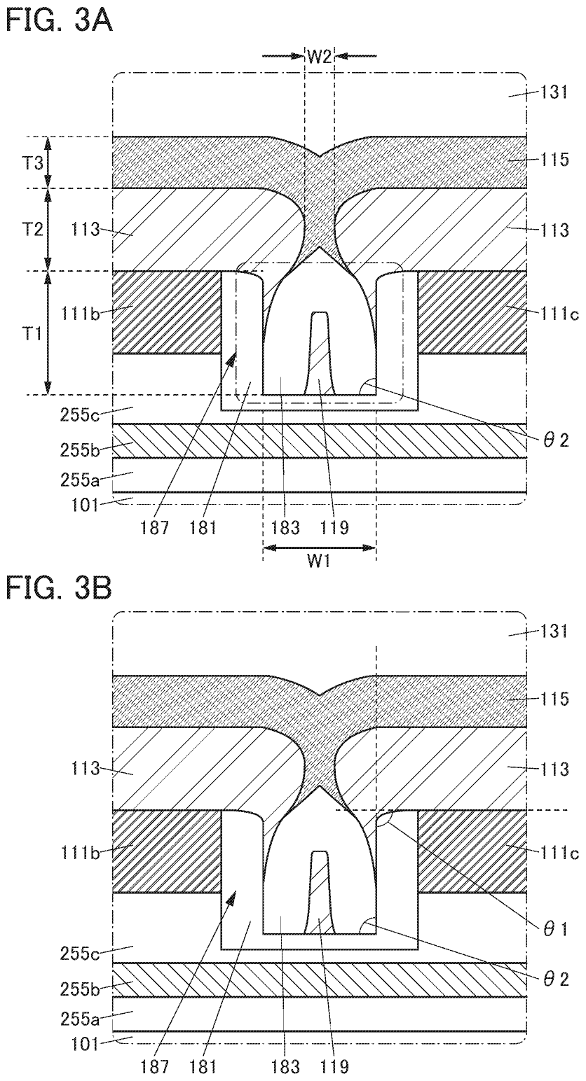

The angle θ1 is preferably within the above range; however, as illustrated in FIG. 3A, a corner of an upper end portion of the insulating layer 181 is rounded in some case. In the case where the corner of the upper end portion of the insulating layer 181 is rounded, the angle θ1 can be defined by a tangent to the top surface of the insulating layer 181 and a tangent to the side surface of the insulating layer 181 that is not in contact with the pixel electrode 111, as illustrated in FIG. 3B, for example. Similarly, the angle θ2 can be defined by a tangent to the top surface of the insulating layer 181 and a tangent to the side surface of the insulating layer 181 that is not in contact with the insulating layer 255c.

An organic layer 119 may be provided in the opening 187. The organic layer 119 is formed when the material of the EL layer 113 reaches the inside of the opening 187 in the formation of the EL layer 113. That is, the organic layer 119 is formed using the same material in the same step as the EL layer 113. FIG. 2 illustrates an example in which the organic layer 119 is provided over the insulating layer 181 in the bottom portion of the opening 187. The bottom portion of the opening 187 may be covered with the organic layer 119 or the insulating layer 181 may be exposed in the bottom portion of the opening 187.

It is preferable that the organic layer 119 not include a region in contact with the EL layer 113. When the organic layer 119 includes a region in contact with the EL layer 113, the EL layers 113 included in the adjacent light-emitting devices 130 are connected through the organic layer 119 and leakage current is generated in some cases. In addition, it is preferable that the organic layer 119 not include a region in contact with the side surface of the insulating layer 181. When the organic layer 119 includes a region in contact with the side surface of the insulating layer 181, the EL layers 113 included in the adjacent light-emitting devices 130 might be connected through the organic layer 119. In the opening 187, the insulating layer 181 preferably includes a region in contact with neither the EL layer 113 nor the organic layer 119.

Here, materials which can be used for the insulating layer 181 will be described.

An inorganic material can be used for the insulating layer 181. For example, one or more of an oxide, a nitride, an oxynitride, and a nitride oxide can be used for the insulating layer 181. The insulating layer 181 may have a single-layer structure or a stacked-layer structure. Examples of the oxide include a silicon oxide, an aluminum oxide, a magnesium oxide, an indium gallium zinc oxide, a gallium oxide, a germanium oxide, an yttrium oxide, a zirconium oxide, a lanthanum oxide, a neodymium oxide, a hafnium oxide, and a tantalum oxide. Examples of the nitride include a silicon nitride and an aluminum nitride. Examples of the oxynitride include a silicon oxynitride and an aluminum oxynitride. Examples of the nitride oxide include a silicon nitride oxide and an aluminum nitride oxide. In particular, when an aluminum oxide, a hafnium oxide, or a silicon oxide formed by an atomic layer deposition (ALD) method is used for the insulating layer 181, the insulating layer 181 having few pin holes and an excellent function of protecting the pixel electrode 111 can be formed. The insulating layer 181 may have a stacked-layer structure of a film formed by an ALD method and a film formed by a sputtering method. The insulating layer 181 may have a stacked-layer structure of an aluminum oxide film formed by an ALD method and a silicon nitride film formed by a sputtering method, for example.

The insulating layer 181 preferably has a function of a barrier insulating layer against at least one of water and oxygen. Alternatively, the insulating layer 181 preferably has a function of inhibiting diffusion of at least one of water and oxygen. Alternatively, the insulating layer 181 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as having low permeability). Alternatively, a barrier property refers to a function of capturing or fixing (also referred to as gettering) a particular substance.

When the insulating layer 181 has a function of a barrier insulating layer or a gettering function, entry of impurities (typically, water and oxygen) that would diffuse into the light-emitting devices from the outside can be inhibited. When entry of impurities is inhibited, an increase in resistance due to oxidation of the pixel electrode 111 can be inhibited, for example. Furthermore, diffusion of impurities into the EL layer 113 through the pixel electrode 111 can be inhibited. Thus, a highly reliable light-emitting device and a highly reliable display device can be provided.

The insulating layer 181 preferably has a low impurity concentration. This can inhibit diffusion of impurities into the EL layer 113 from the insulating layer 181 through the pixel electrode 111 and deterioration of the EL layer 113. In addition, when the impurity concentration of the insulating layer 181 is reduced, a barrier property of the insulating layer 181 against at least one of water and oxygen can be increased. For example, the insulating layer 181 preferably has one of a sufficiently low hydrogen concentration and a sufficiently low carbon concentration, desirably has both of them.

Note that the insulating layer 181 can be formed using a material that can be used for the insulating layer 255c. For example, the same material can be used for the insulating layer 181 and the insulating layer 255c. In that case, a boundary between the insulating layer 181 and the insulating layer 255c is unclear and they cannot be distinguished from each other, so that the insulating layer 181 and the insulating layer 255c are observed as one layer in some cases.

In the opening 187, a gap 183 may be provided in a region where neither the EL layer 113 nor the organic layer 119 is provided. The gap 183 contains, for example, one or more selected from air, nitrogen, oxygen, carbon dioxide, and Group 18 elements (typified by helium, neon, argon, xenon, krypton, and the like). For example, a gas used in the formation of the common electrode 115 is sometimes contained in the gap 183. For example, in the case where the common electrode 115 is formed by a sputtering method using argon, the gap 183 sometimes contains argon. In the case where a gas is contained in the gap 183, the gas can be identified with, for example, a gas chromatography method. Note that the upper end of a region where the gap 183 is provided may be positioned at a higher level than the opening 187.

When a depth T1 of the opening 187 is shallow, a step in the formation surface of the EL layer 113 becomes small, and the EL layers 113 included in the adjacent light-emitting devices 130 might be connected to each other. On the other hand, when a depth T2 of the opening 187 is deep, it takes time to form the opening 187 and the productivity becomes low in some cases. The ratio of the depth T1 of the opening 187 to the thickness T2 of the EL layer 113 (T1/T2) is preferably higher than or equal to 0.5 and lower than or equal to 10.0, further preferably higher than or equal to 0.5 and lower than or equal to 5.0, still further preferably higher than or equal to 0.5 and lower than or equal to 3.0, yet further preferably higher than or equal to 0.8 and lower than or equal to 3.0, yet still further preferably higher than or equal to 1.0 and lower than or equal to 3.0, yet still further preferably higher than or equal to 1.5 and lower than or equal to 3.0, yet still further preferably higher than or equal to 1.5 and lower than or equal to 2.0. When the ratio of the depth T1 of the opening 187 to the thickness T2 of the EL layer 113 (T1/T2) is within the above range, a display device including the island-shaped EL layer 113 can be manufactured with high productivity can be manufactured. Note that the depth T1 of the opening 187 indicates the difference between the position of the highest top surface of the insulating layer 181 and that of the lowest top surface of the insulating layer 181 in a cross-sectional view. The thickness T2 of the EL layer 113 refers to the difference between the position of the top surface of the EL layer 113 and the position of the bottom surface of the EL layer 113 in a region overlapping with the pixel electrode 111 in a cross-sectional view.

When a width W1 of the opening 187 is narrow, the organic layer 119 and the EL layer 113 come in contact with each other and the EL layers 113 included in the adjacent light-emitting devices 130 are connected through the organic layer 119 in some cases. Meanwhile, when the width W1 of the opening 187 is wide, the distance between the light-emitting devices 130 is increased, so that the resolution and the aperture ratio of the display device are reduced in some cases. When the width W1 of the opening 187 is wide, the connection defect due to disconnection of the common electrode 115 or an increase in electric resistance due to the local thinning of the common electrode 115 can be inhibited. The width W1 of the opening 187 is preferably greater than or equal to 50 nm and less than or equal to 500 nm, further preferably greater than or equal to 50 nm and less than or equal to 400 nm, still further preferably greater than or equal to 100 nm and less than or equal to 400 nm, yet further preferably greater than or equal to 100 nm and less than or equal to 300 nm, yet still further preferably greater than or equal to 150 nm and less than or equal to 300 nm, yet still further preferably greater than or equal to 150 nm and less than or equal to 250 nm. Note that the width W1 of the opening 187 indicates the shortest distance between the side surfaces of the insulating layer 181 that face each other in the opening 187 in a cross-sectional view.

As illustrated in FIG. 2 and the like, an end portion of the EL layer 113 is positioned in a region overlapping with the opening 187 in some cases. That is, a distance W2 between the end portions of the adjacent EL layers 113 is smaller than the width W1 of the opening 187 in some cases. A thickness T3 of the common electrode 115 is preferably larger than the distance W2. Note that the distance W2 between the end portions of the EL layers 113 refers to the distance between the outermost portion of the end portion of the EL layer 113 and the end portion positioned on the outermost side of the adjacent the EL layer 113. The thickness T3 of the common electrode 115 refers to a difference between the position of the top surface and the position of the bottom surface of the common electrode 115 in a region overlapping with the pixel electrode 111 in a cross-sectional view. Note that the end portion of the EL layer 113 may be positioned over the insulating layer 181 in the upper portion of the opening 187. The end portion of the EL layer 113 may be positioned over the pixel electrode 111. That is, the distance W2 between the end portions of the adjacent EL layers 113 may be equal to the width W1 of the opening 187 or may be larger than the width W1.

The above-described angle θ1, angle θ2, depth T1, thickness T2, thickness T3, width W1, and distance W2 can be measured by, for example, a scanning electron microscopy (SEM) image, a transmission electron microscope (TEM) image, or a scanning transmission electron microscopy (STEM) image of a cross section of the light-emitting device 130.

Although FIG. 1B and the like illustrate an example in which end portions of the pixel electrode 111a, the pixel electrode 111b, the pixel electrode 111c, and a conductive layer 123 are vertical or substantially vertical, one embodiment of the present invention is not limited thereto. The end portions of the pixel electrode 111a, the pixel electrode 111b, the pixel electrode 111c, and the conductive layer 123 may each have a tapered shape. Specifically, the end portions of the pixel electrode 111a, the pixel electrode 111b, the pixel electrode 111c, and the conductive layer 123 may each have a tapered shape.

As illustrated in FIG. 1B and the like, an insulating layer covering an end portion of the top surface of the pixel electrode 111 is not provided between the pixel electrode 111 and the EL layer 113 in the display device of one embodiment of the present invention. Thus, the distance between the adjacent light-emitting devices 130 can be extremely shortened. Accordingly, the display device can have a high resolution or a high definition. In addition, a mask for forming the insulating layer is not needed, which leads to a reduction in manufacturing cost of the display device.

Light emitted from the EL layer 113 can be extracted efficiently with a structure where an insulating layer covering the end portion of the top surface of the pixel electrode 111 is not provided between the pixel electrode 111 and the EL layer 113, i.e., a structure where an insulating layer is not provided between the pixel electrode 111 and the EL layer 113. Therefore, the display device of one embodiment of the present invention can significantly reduce the viewing angle dependence. A reduction in the viewing angle dependence leads to an increase in visibility of an image on the display device. For example, in the display device of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction.

The light-emitting device 130 may have either a single structure (a structure including only one light-emitting unit) or a tandem structure (a structure including a plurality of light-emitting units). The light-emitting unit includes at least one light-emitting layer.

The EL layer 113 includes at least a light-emitting layer. In addition, the EL layer 113 may include one or more of a hole-injection layer, a hole-transport layer, a hole-blocking layer, a charge-generation layer, an electron-blocking layer, an electron-transport layer, and an electron-injection layer.

For example, the EL layer 113 can contain a light-emitting material emitting blue light and a light-emitting material emitting visible light having a longer wavelength than blue light. For example, a structure containing a light-emitting material emitting blue light and a light-emitting material emitting yellow light, or a structure containing a light-emitting material emitting blue light, a light-emitting material emitting green light, and a light-emitting material emitting red light can be used for the EL layer 113.

As each of the light-emitting device 130a, the light-emitting device 130b, and the light-emitting device 130c, for example, a single-structure light-emitting device including two light-emitting layers, which are a light-emitting layer emitting yellow (Y) light and a light-emitting layer emitting blue (B) light, or a single-structure light-emitting device including three light-emitting layers, which are a light-emitting layer emitting red (R) light, a light-emitting layer emitting green (G) light, and a light-emitting layer emitting blue light, can be used. As examples of the number of stacked light-emitting layers and the order of colors thereof, a three-layer structure of R, G, and B and a three-layer structure of R, B, and G from the anode side can be given. Another layer (also referred to as a buffer layer) may be provided between two light-emitting layers.

In the case where the light-emitting device 130 having a tandem structure is used, examples of applicable structures are as follows: a two-unit tandem structure including a light-emitting unit that emits yellow light and a light-emitting unit that emits blue light; a two-unit tandem structure including a light-emitting unit that emits red light and green light and a light-emitting unit that emits blue light; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from an anode side include a two-unit structure of B and Y; a two-unit structure of B and X; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting device 130 having a tandem structure is used, the EL layer 113 includes a plurality of light-emitting units. A charge-generation layer is preferably provided between the light-emitting units.

The light-emitting unit includes at least one light-emitting layer. For example, when emission colors of the plurality of light-emitting units are complementary to each other, the light-emitting device 130 can emit white light. The light-emitting unit may include one or more of a hole-injection layer, a hole-transport layer, a hole-blocking layer, an electron-blocking layer, an electron-transport layer, and an electron-injection layer.

Note that in the case where the light-emitting device 130, which is configured to emit white light, has a microcavity structure, light of a specific wavelength such as red, green, blue, or infrared light is sometimes intensified and emitted.

The EL layer 113 may include a hole-injection layer, a hole-transport layer, a light-emitting layer, and an electron-transport layer in this order, for example. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

The EL layer 113 may include an electron-injection layer, an electron-transport layer, a light-emitting layer, and a hole-transport layer in this order, for example. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

As described above, the EL layer 113 preferably includes a light-emitting layer and a carrier-transport layer (an electron-transport layer or a hole-transport layer) over the light-emitting layer. Alternatively, the EL layer 113 preferably includes a light-emitting layer and a carrier-blocking layer (a hole-blocking layer or an electron-blocking layer) over the light-emitting layer. Alternatively, the EL layer 113 preferably includes a light-emitting layer, a carrier-blocking layer over the light-emitting layer, and a carrier-transport layer over the carrier-blocking layer. Since the surface of the EL layer 113 is exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved.

The upper temperature limits of the compounds contained in the EL layer 113 are each preferably higher than or equal to 100° C. and lower than or equal to 180° C. or higher than or equal to 120° C. and lower than or equal to 180° C., further preferably higher than or equal to 140° C. and lower than or equal to 180° C. For example, the glass transition point (Tg) of these compounds is preferably higher than or equal to 100° C. and lower than or equal to 180° C. or higher than or equal to 120° C. and lower than or equal to 180° C., further preferably higher than or equal to 140° C. and lower than or equal to 180° C.

In particular, the upper temperature limits of the functional layers provided over the light-emitting layer are preferably high. It is further preferable that the upper temperature limit of the functional layer provided over and in contact with the light-emitting layer be high. When the functional layer has high heat resistance, the light-emitting layer can be effectively protected and damage to the light-emitting layer can be reduced.

In addition, the upper temperature limit of the light-emitting layer is preferably high. In this case, the light-emitting layer can be inhibited from being damaged by heating and being decreased in emission efficiency and lifetime.

The light-emitting layer contains a light-emitting substance (also referred to as a light-emitting organic compound, a guest material, or the like) and an organic compound (also referred to as a host material or the like). Since the light-emitting layer contains more organic compound than light-emitting substance, Tg of the organic compound can be used as an indicator of the upper temperature limit of the light-emitting layer.

The EL layer 113 includes a first light-emitting unit, a charge-generation layer, and a second light-emitting unit, for example.

The second light-emitting unit preferably includes a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved. Note that in the case where three or more light-emitting units are provided, the uppermost light-emitting unit preferably includes a light-emitting layer and one or both of a carrier-transport layer and a carrier-blocking layer over the light-emitting layer.

FIG. 1B illustrates an example where the end portion of the EL layer 113 is positioned more outward from an end portion of the pixel electrode 111. Such a structure enables the entire top surface of the pixel electrode 111 to be a light-emitting region, and the aperture ratio can be easily increased as compared with the structure where the end portion of the island-shaped EL layer 113 is positioned inward from the end portion of the pixel electrode 111.

The common electrode 115 is provided over the EL layer 113. The common electrode 115 is shared by the light-emitting device 130a, the light-emitting device 130b, and the light-emitting device 130c. The common electrode 115 shared by a plurality of light-emitting devices 130 is electrically connected to the conductive layer 123 provided in the connection portion 140 (see FIG. 1B). The conductive layer 123 is preferably formed using a conductive layer formed using the same material and in the same step as the pixel electrode 111a, the pixel electrode 111b, and the pixel electrode 111c.

The protective layer 131 is preferably provided over the light-emitting device 130a, the light-emitting device 130b, and the light-emitting device 130c. Providing the protective layer 131 can improve the reliability of the light-emitting device 130. The protective layer 131 may have a single-layer structure or a stacked-layer structure of two or more layers.

There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting device by preventing oxidation of the common electrode 115 and inhibiting entry of impurities (e.g., moisture and oxygen) into the light-emitting device, for example; thus, the reliability of the display device can be improved.

For the protective layer 131, inorganic films containing an oxide, a nitride, an oxynitride, and a nitride oxide can be used, for example. Specific examples of these inorganic films are as listed in the description of the insulating layer 181. In particular, the protective layer 131 preferably includes a nitride insulator or a nitride oxide, and further preferably includes a nitride.

For the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. The use of such a stacked-layer structure can inhibit diffusion of impurities (such as water and oxygen) to the EL layer 113 side.

Furthermore, the protective layer 131 may include an organic film. As an organic material which can be used for the protective layer 131, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used, for example. The protective layer 131 may include both an organic film and an inorganic film. The protective layer 131 may have a stacked-layer structure of an organic film and an inorganic film, for example.

The protective layer 131 may have a stacked-layer structure of layers which are formed by different formation methods. Specifically, a stacked-layer structure of a first layer formed by an ALD method and a second layer formed by a sputtering method over the first layer can be employed.

A light-blocking layer may be provided on the surface of the substrate 120 on the resin layer 122 side. Moreover, a variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 120. For example, it is preferable to provide, as the surface protective layer, a glass layer or a silica layer (SiOₓ layer) because the surface contamination and generation of damage can be inhibited. For the surface protective layer, DLC (diamond like carbon), aluminum oxide (AlOₓ), a polyester-based material, a polycarbonate-based material, or the like may be used. Note that for the surface protective layer, a material having high visible light transmittance is preferably used. For the surface protective layer, a material with high hardness is preferably used.

For the substrate 120, glass, quartz, ceramic, sapphire, a resin, a metal, an alloy, a semiconductor, or the like can be used. For the substrate through which light from the light-emitting device is extracted, a material that transmits the light is used. When a flexible material is used for the substrate 120, the display device can have increased flexibility. Furthermore, a polarizing plate may be used as the substrate 120.

For the substrate 120, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display device, a highly optically isotropic substrate is preferably used as the substrate included in the display device. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display device might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. Alternatively, an adhesive sheet or the like may be used.

FIG. 1B illustrates an example in which the coloring layers 132R, 132G, and 132B are directly provided over the light-emitting devices 130a, 130b, and 130c with the protective layer 131 therebetween. With such a structure, the alignment accuracy of the light-emitting devices and the coloring layers can be improved. Such a structure is preferably employed, in which case the distance between the light-emitting devices and the coloring layers can be reduced and thus, color mixing can be inhibited and the viewing angle characteristics can be improved.

A structure example different from that of the above-described display device will be described below. Note that description of the same portions as those in the display device described above is omitted in some cases. Furthermore, in drawings that are referred to later, the same hatching pattern is applied to portions having functions similar to those in the display device described above, and the portions are not denoted by reference numerals in some cases.

### Structure Example 2

FIG. 4A is a cross-sectional view of the display device of one embodiment of the present invention. FIG. 1A can be referred to for a top view. FIG. 4B is an enlarged view of part of a cross-sectional view illustrated in FIG. 4A.

The display device illustrated in FIG. 4A and the like is different from the display device described in <Structure example 1> mainly in that the opening 187 is provided in the insulating layer 181 and the insulating layer 255c.

FIG. 4A and the like illustrate an example in which the opening 187 reaches the insulating layer 255b. In the bottom portion of the opening 187, the organic layer 119 is provided over the insulating layer 255b. The bottom portion of the opening 187 may be covered with the organic layer 119 or the insulating layer 255b may be exposed in the bottom portion of the opening 187.

Note that the opening 187 may be provided in the insulating layer 181, the insulating layer 255c, and the insulating layer 255b. Alternatively, the opening 187 may be provided in the insulating layer 181, the insulating layer 255c, and the insulating layer 255b.

### Structure Example 3

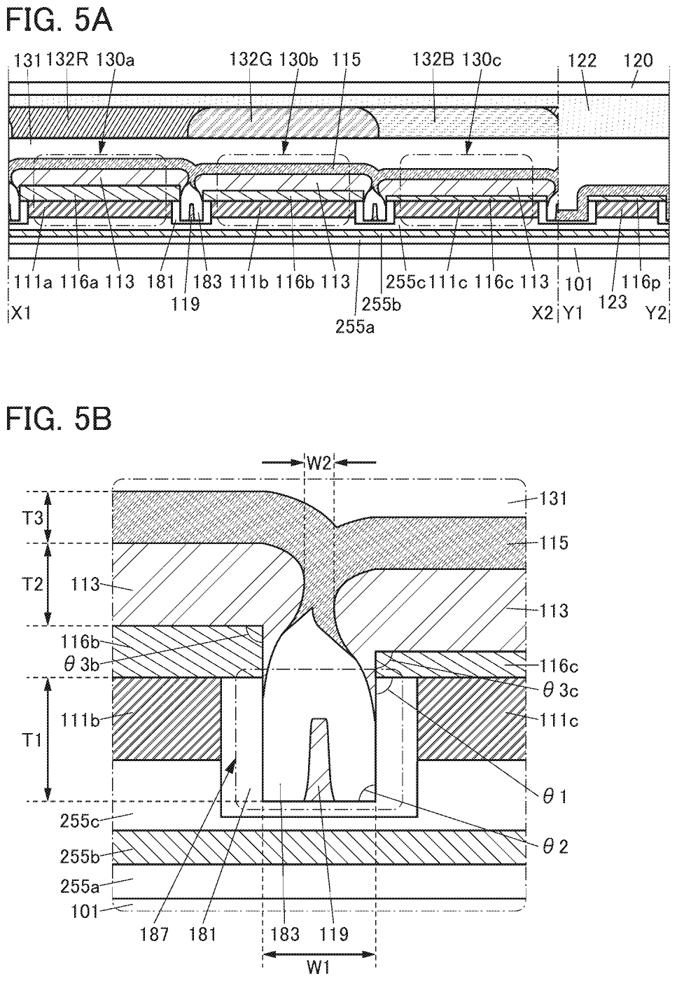

FIG. 5A illustrates a cross-sectional view of the display device of one embodiment of the present invention. FIG. 1A can be referred to for a top view. FIG. 5B is an enlarged view of part of the cross-sectional view illustrated in FIG. 5A.

The display device illustrated in FIG. 5A and the like is different from the display device described in <Structure example 1> mainly in including a conductive layer 116a, a conductive layer 116b, and a conductive layer 116c.

The display device illustrated in FIG. 5A and the like employs a microcavity structure. Therefore, one of the pair of electrodes of the light-emitting device 130 is preferably an electrode having properties of transmitting and reflecting visible light (a transflective electrode), and the other is preferably an electrode having a property of reflecting visible light (a reflective electrode). When the light-emitting device 130 has a microcavity structure, light obtained from the light-emitting layer can be resonated between the electrodes, whereby light emitted from the light-emitting device 130 can be intensified. In addition, emission intensity of light with a specific wavelength can be increased, so that the color purity can be increased. Light (monochromatic light) with different wavelengths can be extracted even if the EL layers 113 with the same structure are included. Furthermore, the emission intensity of light with a specific wavelength in the front direction can be increased, whereby power consumption can be reduced. Note that, with a combination of the microcavity structure and the coloring layer, color purity can be increased.

The light-emitting device 130a includes the conductive layer 116a between the pixel electrode 111a and the EL layer 113. The light-emitting device 130b includes the conductive layer 116b between the pixel electrode 111b and the EL layer 113. The light-emitting device 130c includes the conductive layer 116c between the pixel electrode 111c and the EL layer 113. The conductive layer 116a, the conductive layer 116b, and the conductive layer 116c each function as an optical adjustment layer in the light-emitting device 130. Optical adjustment can be performed by controlling the thickness of an optical adjustment layer. Specifically, the distance between the pixel electrode 111 and the common electrode 115 is preferably adjusted to mλ/2 (m is an integer greater than or equal to 1) or the neighborhood thereof, where λ is the wavelength of light obtained from the light-emitting layer.

In the display device of one embodiment of the present invention, the EL layers 113 included in the light-emitting device 130a, the light-emitting device 130b, and the light-emitting device 130c are formed using the same material in the same step; thus, the thicknesses of the EL layers 113 are equal or substantially equal to each other. Thus, in order to vary the distance between the pixel electrode 111 and the common electrode 115, the thicknesses of the conductive layer 116a, the conductive layer 116b, and the conductive layer 116c that are interposed between the pixel electrode 111 and the common electrode 115 are made different from each other.

Here, an example where m described above is common to the light-emitting device 130a, the light-emitting device 130b, and the light-emitting device 130c is described. The conductive layer 116 has a large thickness in the light-emitting device 130 including a region overlapping with the coloring layer 132 that transmits light with a long wavelength, and the conductive layer 116 has a small thickness in the light-emitting device 130 including a region overlapping with the coloring layer 132 that transmits light with a short wavelength. For example, in the case where the coloring layer 132R transmits red light, the coloring layer 132G transmits green light, and the coloring layer 132B transmits blue light, the thickness of the conductive layer 116a is the largest, followed in order by those of the conductive layer 116b and the conductive layer 116c as illustrated in FIG. 5A.

The conductive layer 116a, the conductive layer 116b, and the conductive layer 116c that are provided over the pixel electrode 111 can each be regarded as having a function of a pixel electrode.

The conductive layer 123 provided in the connection portion 140 is electrically connected to the common electrode 115 through a conductive layer 116p. The conductive layer 116p can be formed in the same step as, for example, the conductive layer 116a, the conductive layer 116b, or the conductive layer 116c. For example, the conductive layer 116p can be formed in the same step as the conductive layer 116c, and as illustrated in FIG. 5A, the thickness of the conductive layer 116p can be equal or substantially equal to the thickness of the conductive layer 116c. Note that in the connection portion 140, the conductive layer 123 and the common electrode 115 may be in direct contact with each other and be electrically connected to each other without providing the conductive layer 116p.

A side surface of the conductive layer 116a is aligned or substantially aligned with the side surface of the opening 187. A side surface of the conductive layer 116b is aligned or substantially aligned with the side surface of the opening 187. A side surface of the conductive layer 116c is aligned or substantially aligned with the side surface of the opening 187. A side surface of the conductive layer 116p is aligned or substantially aligned with the side surface of the opening 187. When the side surfaces of the conductive layer 116a, the conductive layer 116b, and the conductive layer 116c are aligned with the side surface of the opening 187, the height of the step in the formation surface of the EL layer 113 corresponds to the sum of the depth T1 of the opening 187 and the thickness of the conductive layer 116. Thus, the step in the formation surface of the EL layer 113 becomes large, so that the island-shaped EL layer 113 can be easily formed. For example, in FIG. 5B, the height of the step in the formation surface of the EL layer 113 provided over the conductive layer 116b corresponds to the sum of the depth T1 of the opening 187 and the thickness of the conductive layer 116b. The height of step in the formation surface of the EL layer 113 provided over the conductive layer 116c corresponds to the sum of the depth T1 of the opening 187 and the thickness of the conductive layer 116c.

In the case where the side surface of the conductive layer 116a and the side surface of the opening 187 are aligned or substantially aligned with each other and the top surface shapes of these are the same or substantially the same, it can be said that the outlines of the conductive layer 116a and the opening 187 overlap with each other at least partly in the top view. However, in some cases, the outlines do not exactly overlap with each other and the outline of the conductive layer 116a is located inward from the outline of the opening 187 or the outline of the conductive layer 116a is located outward from the outline of the opening 187; such a case is also represented as “side surfaces are substantially aligned with each other” or “top surface shapes are the same or substantially the same”.

The state where the side surface of the conductive layer 116a is aligned or substantially aligned with the side surface of the opening 187 can be regarded as the state where the side surface of the insulating layer 181 on the side not in contact with the pixel electrode 111a (the opening 187 side) is aligned or substantially aligned with the side surface of the conductive layer 116a. The same applies to the conductive layer 116b and the conductive layer 116c. The state where the side surface of the conductive layer 116p is aligned or substantially aligned with the side surface of the opening 187 can be regarded as the state where the side surface of the insulating layer 181 on the side not in contact with the conductive layer 123 (the opening 187 side) is aligned or substantially aligned with the side surface of the conductive layer 116p.

For example, the opening 187 can be formed using a mask for forming the conductive layer 116a, the conductive layer 116b, the conductive layer 116c, or the conductive layer 116p.

Note that the side surface of the conductive layer 116a can be referred to as an end portion of the conductive layer 116a. The same applies to the conductive layer 116b, the conductive layer 116c, and the conductive layer 116p.

The EL layer 113 is provided to cover the top surfaces of the conductive layer 116a, the conductive layer 116b, and the conductive layer 116c. The EL layer 113 may include regions in contact with the side surfaces of the conductive layer 116a, the conductive layer 116b, and the conductive layer 116c. Furthermore, the EL layer 113 may include regions in contact with the side surfaces of the conductive layer 116a, the conductive layer 116b, and the conductive layer 116c and part of the side surface of the insulating layer 181. When the EL layer 113 covers the entire side surfaces of the conductive layer 116a, the conductive layer 116b, and the conductive layer 116c, the common electrode 115 is inhibited from being in contact with the conductive layer 116a, the conductive layer 116b, and the conductive layer 116c; therefore, a short circuit between the common electrode 115 and the pixel electrode can be inhibited.

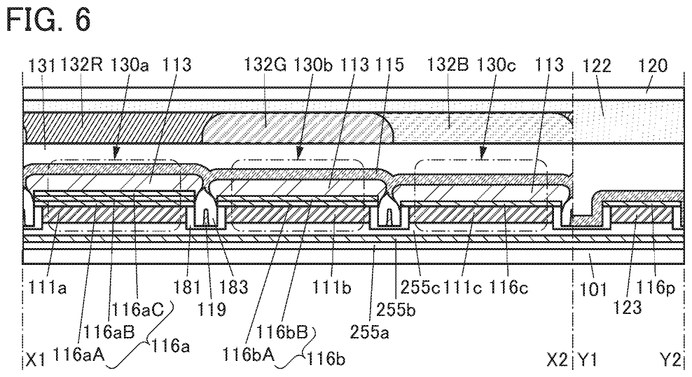

Although the conductive layer 116a, the conductive layer 116b, the conductive layer 116c, and the conductive layer 116p each have a single-layer structure in FIG. 5A, one embodiment of the present invention is not limited thereto. Some or all of the conductive layer 116a, the conductive layer 116b, the conductive layer 116c, and the conductive layer 116p may have a stacked-layer structure. FIG. 6 illustrates an example where the conductive layer 116a has a three-layer structure of a conductive layer 116aA, a conductive layer 116aB, and a conductive layer 116aC, the conductive layer 116b has a two-layer structure of a conductive layer 116bA and a conductive layer 116bB, and the conductive layer 116c and the conductive layer 116p each have a single-layer structure.

An angle formed between the top surface and the side surface of the conductive layer 116 is preferably 90° or substantially 90°. FIG. 5B illustrates an angle θ3b formed between the top surface and the side surface of the conductive layer 116b and an angle θ3c formed between the top surface and the side surface of the conductive layer 116c. The angle θ3b and the angle θ3c are preferably greater than or equal to 80° and less than or equal to 110°, further preferably greater than or equal to 80° and less than or equal to 100°, still further preferably greater than or equal to 85° and less than or equal to 100°, yet still further preferably greater than or equal to 85° and less than or equal to 95°. The same applies to an angle θ3a formed between the top surface and the side surface of the conductive layer 116a. When the angles formed between the top surfaces and the side surfaces of the conductive layers 116 are within the above range, a disconnection region of the EL layer 113 can be provided. Note that the angle formed between the top surface and the side surface of the conductive layer 116 may be rounded so that the angle θ3a, the angle θ3b, and the angle θ3c are not measured precisely.

### Structure Example 4

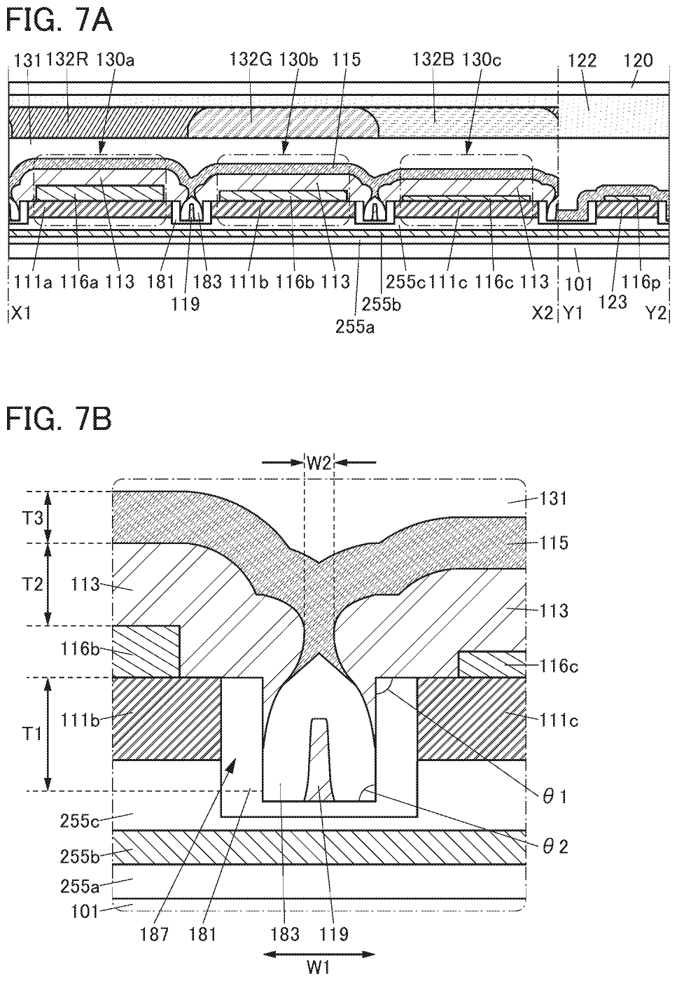

FIG. 7A is a cross-sectional view of the display device of one embodiment of the present invention. FIG. 1A can be referred to for a top view. FIG. 7B is an enlarged view of part of the cross-sectional view illustrated in FIG. 7A.

The display device illustrated in FIG. 7A and the like is different from the display device described in <Structure example 3> mainly in that the side surfaces of the conductive layer 116a, the conductive layer 116b, the conductive layer 116c, and the conductive layer 116p are not aligned with the side surface of the opening 187. It can be said that the side surfaces of the conductive layer 116a, the conductive layer 116b, and the conductive layer 116c are not aligned with the side surface of the insulating layer 181 on the side not in contact with the pixel electrode 111 and the side surface of the conductive layer 116p is not aligned with the side surface of the insulating layer 181 on the side not in contact with the conductive layer 123.

For example, the opening 187 can be formed using a mask different from the mask for forming the conductive layer 116a, the conductive layer 116b, the conductive layer 116c, or the conductive layer 116p.

FIG. 7A and the like illustrate an example where the side surface of the conductive layer 116a is positioned over the pixel electrode 111a, the side surface of the conductive layer 116b is positioned over the pixel electrode 111b, the side surface of the conductive layer 116c is positioned over the pixel electrode 111c, and the side surface of the conductive layer 116p is positioned over the conductive layer 123. The EL layer 113 includes regions in contact with parts of the top surfaces of the pixel electrode 111a, the pixel electrode 111b, and the pixel electrode 111c. The EL layer 113 has a region in contact with the top surface of the insulating layer 181. The side surfaces of the conductive layer 116a, the conductive layer 116b, the conductive layer 116c, and the conductive layer 116p may be positioned over the insulating layer 181. Alternatively, the side surfaces of the conductive layer 116a, the conductive layer 116b, the conductive layer 116c, and the conductive layer 116p may be positioned over the pixel electrode 111a, the pixel electrode 111b, and the pixel electrode 111c.

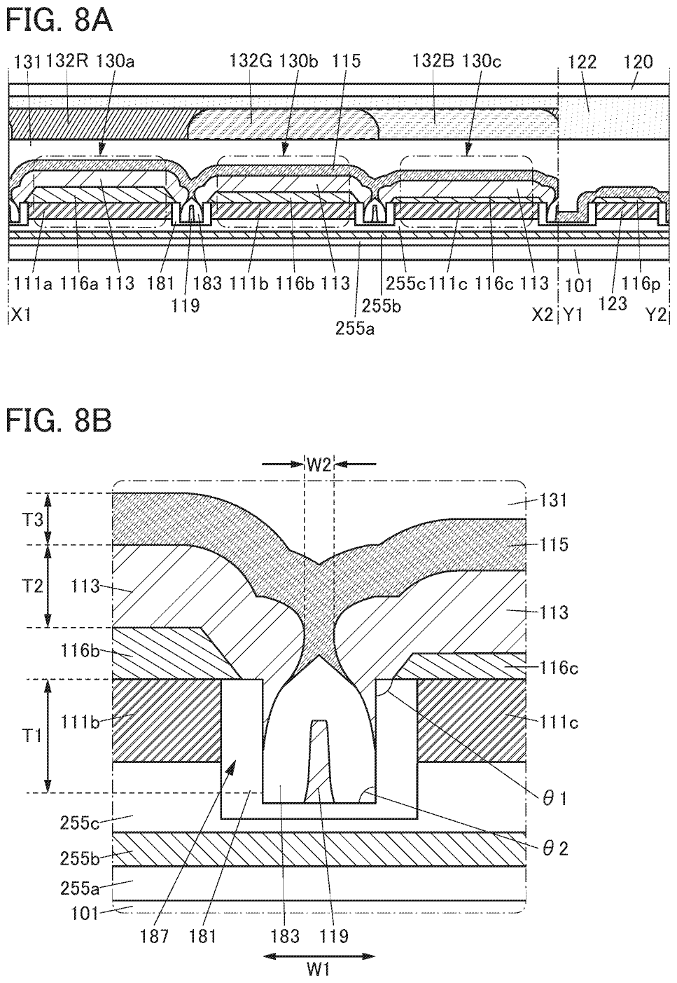

In the case where the side surfaces of the conductive layer 116a, the conductive layer 116b, and the conductive layer 116c are not aligned with the side surface of the opening 187, the end portions of the conductive layer 116a, the conductive layer 116b, and the conductive layer 116c may each have a tapered shape as illustrated in FIG. 8A and FIG. 8B. The angles formed between the top surfaces and the side surfaces of the conductive layer 116a, the conductive layer 116b, and the conductive layer 116c may be 90° but are not necessarily 90°.

### Structure Example 5

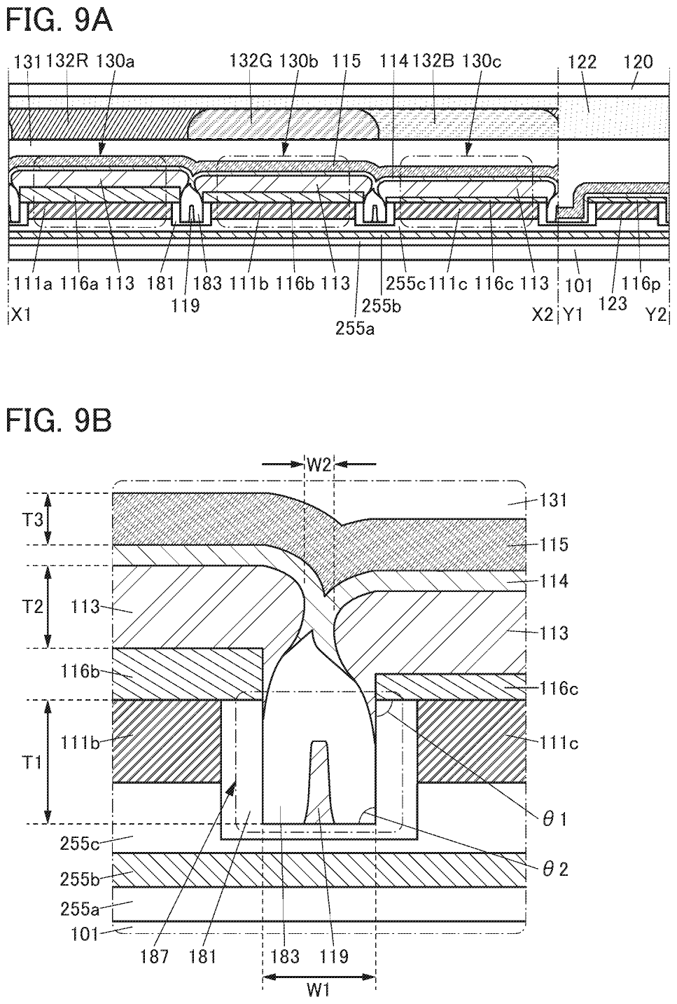

FIG. 9A illustrates a cross-sectional view of the display device of one embodiment of the present invention. FIG. 1A can be referred to for a top view. FIG. 9B is an enlarged view of part of the cross-sectional view illustrated in FIG. 9A.

The display device illustrated in FIG. 9A and the like is different from the display device illustrated in <Structure example 3> mainly in including a common layer 114.

The common layer 114 is provided between the EL layer 113 and the common electrode 115. The common layer 114 is provided to cover the EL layer 113 and shared by the light-emitting device 130a, the light-emitting device 130b, and the light-emitting device 130c. The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer.

The common layer 114 can be formed by a method such as an evaporation method (including a vacuum evaporation method), a transfer method, a printing method, an inkjet method, or a coating method.

FIG. 9A and the like illustrate an example in which the common layer 114 is provided over the conductive layer 116p and the conductive layer 123 and the common electrode 115 are electrically connected to each other through the common layer 114 and the conductive layer 116p. Note that in the connection portion 140, and the conductive layer 116p and the common electrode 115 may be in direct contact with each other to be electrically connected to each other without providing the common layer 114 over the conductive layer 116p. For example, by using a mask for specifying a formation area of the common layer 114 (also referred to as an area mask or a rough metal mask to be distinguished from a fine metal mask), the common layer 114 can be formed only in a desired region. When the area mask used at the time of forming the common layer 114 and the area mask used at the time of forming the common electrode 115 are different from each other, the region where the common layer 114 is formed and the region where the common electrode 115 is formed can be different from each other.

### Structure Example 6

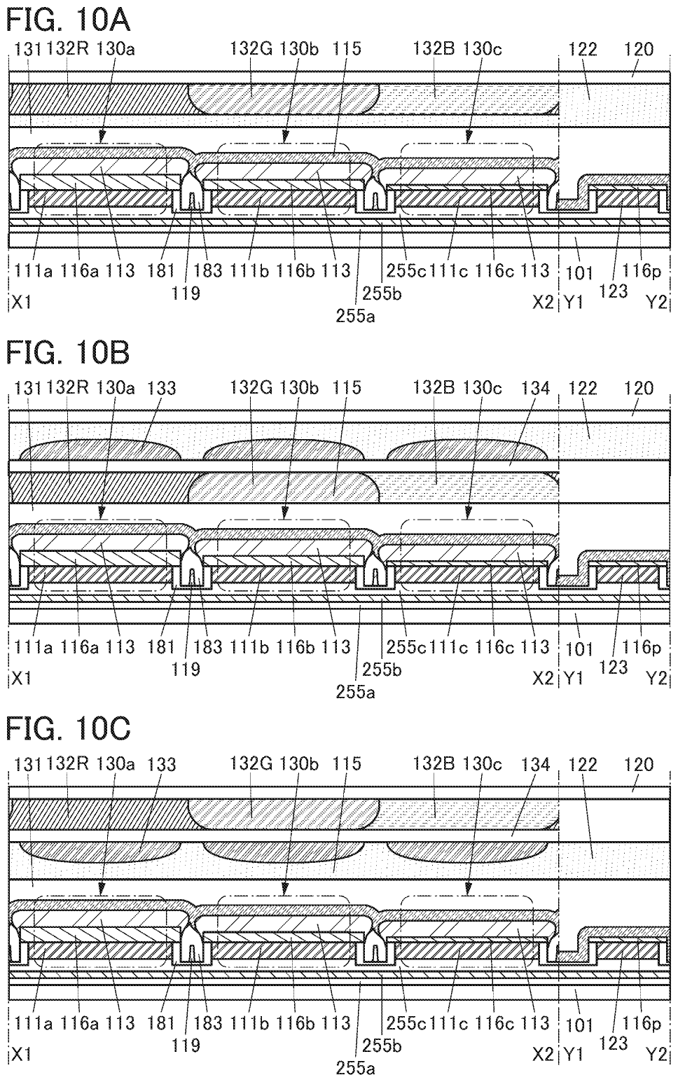

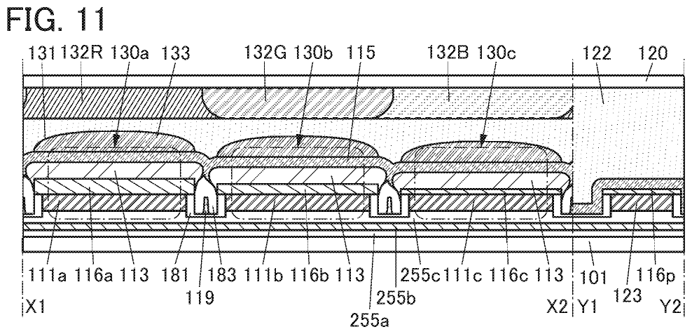

FIG. 10A to FIG. 10C and FIG. 11 are cross-sectional views of the display device of one embodiment of the present invention. FIG. 1A can be referred to for a top view.

As illustrated in FIG. 10A, the substrate 120 provided with the coloring layers 132 may be attached to the protective layer 131 with the resin layer 122. By providing the coloring layer 132 for the substrate 120, the heat treatment temperature in the formation step of the coloring layer 132 can be increased.

As illustrated in FIG. 10B and FIG. 10C, a lens array 133 may be provided in the display device. The lens array 133 can be provided in regions overlapping with the light-emitting devices 130.

FIG. 10B illustrates an example in which the coloring layer 132R, the coloring layer 132G, and the coloring layer 132B are provided over the light-emitting device 130a, the light-emitting device 130b, and the light-emitting device 130c with the protective layer 131 therebetween, an insulating layer 134 is provided over the coloring layer 132R, the coloring layer 132G, and the coloring layer 132B, and the lens array 133 is provided over the insulating layer 134. The coloring layer 132R, the coloring layer 132G, the coloring layer 132B, and the lens array 133 are directly formed over the substrate provided with the light-emitting devices 130, whereby the accuracy of positional alignment of the light-emitting devices and the coloring layers 132 or the lens array 133 can be enhanced.

In FIG. 10B, light emitted by the light-emitting device 130 passes through the coloring layer 132 and then passes through the lens array 133, resulting in being extracted to the outside of the display device. The distance between the light-emitting device 130 and the coloring layer 132 is reduced, so that color mixture can be inhibited and the viewing angle characteristics can be improved, which is preferable. Note that the lens array 133 may be provided over the light-emitting device and the coloring layer 132 may be provided over the lens array 133.

FIG. 10C illustrates an example in which the substrate 120 provided with the coloring layer 132R, the coloring layer 132G, the coloring layer 132B, and the lens array 133 is attached onto the protective layer 131 with the resin layer 122. The substrate 120 is provided with the coloring layer 132R, the coloring layer 132G, the coloring layer 132B, and the lens array 133, whereby the heat treatment temperature in the forming step of them can be increased.

FIG. 10C illustrates an example where the coloring layers 132R, 132G, and 132B are provided in contact with the substrate 120, the insulating layer 134 is provided in contact with the coloring layers 132R, 132G, and 132B, and the lens array 133 is provided in contact with the insulating layer 134.

In FIG. 10C, light emitted from the light-emitting device passes through the lens array 133 and then passes through the coloring layer, resulting in being extracted to the outside of the display device. Note that the lens array 133 may be provided in contact with the substrate 120, the insulating layer 134 may be provided in contact with the lens array 133, and the coloring layer may be provided in contact with the insulating layer 134. In this case, light emitted from the light-emitting device passes through the coloring layer and then passes through the lens array 133, resulting in being extracted to the outside of the display device. Note that as illustrated in FIG. 10B and FIG. 10C, it is preferable that a region where the coloring layer 132R and the coloring layer 132G overlap with each other be provided between the adjacent lens arrays 133. Providing a region where coloring layers of different colors overlap with each other can inhibit color mixture of light emitted from the light-emitting devices.

FIG. 11 illustrates an example in which the lens array 133 is provided over the light-emitting devices 130a, 130b, and 130c with the protective layer 131 therebetween, and the substrate 120 provided with the coloring layer 132R, the coloring layer 132G, and the coloring layer 132B is attached onto the lens array 133 and the protective layer 131 with the resin layer 122.

Unlike in FIG. 11, the lens array 133 may be provided on the substrate 120 and the coloring layer may be formed directly over the protective layer 131. In this manner, one of the lens array and the coloring layer may be provided over the protective layer 131 and the other may be provided over the substrate 120.

Although FIG. 10A to FIG. 10C illustrate an example in which a layer having a planarization function is used as the protective layer 131, the protective layer 131 does not necessarily have a planarization function as illustrated in FIG. 11. For example, the protective layer 131 can have a flat top surface when formed using an organic film. Alternatively, the protective layer 131 illustrated in FIG. 11 can be formed using an inorganic film, for example.

The lens array 133 may include a convex surface facing the substrate 120 side or a convex surface facing the light-emitting device side.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used, for example. The lens array 133 may be directly formed over the substrate or the light-emitting device; alternatively, a lens array separately formed may be attached thereto.

In the display device of one embodiment of the present invention, an island-shaped EL layer 113 is provided in each light-emitting device 130, which can inhibit generation of leakage current between the subpixels. Thus, it is possible to prevent crosstalk due to unintended light emission, so that a display device with extremely high contrast can be achieved. Furthermore, the island-shaped EL layer 113 can be formed without using a fine metal mask, so that the display device with high resolution and a high aperture ratio can be achieved. Moreover, the productivity of the display device can be increased.

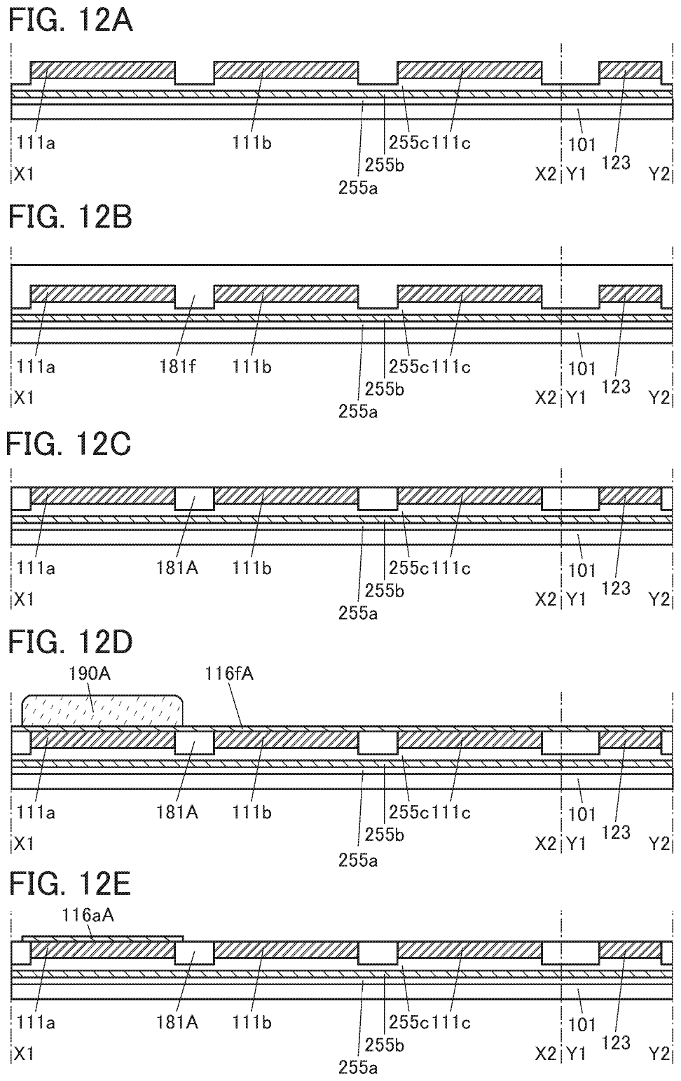

A method for manufacturing the display device of one embodiment of the present invention will be described with reference to FIG. 12 to FIG. 14. Note that as for a material and a formation method of each component, portions similar to the portions described above are not described in some cases.

Here, the manufacturing method is described using the display device illustrated in FIG. 6 as an example. FIG. 12 to FIG. 14 each illustrate a cross-sectional view along the dashed-dotted line X1-X2 and a cross-sectional view along the dashed-dotted line Y1-Y2 in FIG. 1A side by side.

Thin films included in the display device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of the CVD method include a plasma enhanced chemical vapor deposition (PECVD: Plasma Enhanced CVD) method and a thermal CVD method. An example of a thermal CVD method is a metal organic chemical vapor deposition (MOCVD) method.

Alternatively, the thin films included in the display device (e.g., insulating films, semiconductor films, and conductive films) can be formed by a wet deposition method such as spin coating, dipping, spray coating, ink-jetting, dispensing, screen printing, offset printing, a doctor knife method, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

The thin films included in the display device can be processed by a photolithography method or the like. Alternatively, the thin films may be processed by a nanoimprinting method, a sandblasting method, a lift-off method, or the like. Alternatively, island-shaped thin films may be directly formed by a deposition method using a shielding mask such as a metal mask.

There are the following two typical examples of a photolithography method. In one of the methods, a resist mask is formed over a thin film to be processed, the thin film is processed by etching or the like, and then the resist mask is removed. In the other method, after a photosensitive thin film is deposited, light exposure and development are performed, so that the thin film is processed into a desired shape.

As light used for light exposure in a photolithography method, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Light exposure may be performed by liquid immersion exposure technique. As the light used for light exposure, extreme ultraviolet (EUV) light or X-rays may also be used. Furthermore, instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblasting method, or the like can be used.

### <Example of Manufacturing Method>

First, the insulating layer 255a, the insulating layer 255b, and the insulating layer 255c are formed in this order over the layer 101 including transistors. Next, the pixel electrode 111a, the pixel electrode 111b, the pixel electrode 111c and the conductive layer 123 are formed over the insulating layer 255c (FIG. 12A). The pixel electrode can be formed by a sputtering method or a vacuum evaporation method, for example.

When the pixel electrode 111a, the pixel electrode 111b, the pixel electrode 111c, and the conductive layer 123 are formed, part of the insulating layer 255c in a region not overlapping with the pixel electrode 111a, the pixel electrode 111b, the pixel electrode 111c, or the conductive layer 123 may be removed. In this case, the thickness of the insulating layer 255c in the region not overlapping with any of the pixel electrode 111a, the pixel electrode 111b, the pixel electrode 111c, and the conductive layer 123 is smaller than the thickness of the insulating layer 255c in a region overlapping with the pixel electrode 111a, the pixel electrode 111b, the pixel electrode 111c, or the conductive layer 123.

Next, an insulating film 181f to be the insulating layer 181 is formed to cover the pixel electrode 111a, the pixel electrode 111b, the pixel electrode 111c, the conductive layer 123, and the insulating layer 255c (FIG. 12B).

Next, part of the insulating film 181f is removed to expose the pixel electrode 111a, the pixel electrode 111b, the pixel electrode 111c, and the conductive layer 123 and to form an insulating layer 181A (FIG. 12C). The insulating film 181f can be removed by a dry etching method or a chemical mechanical polishing (CMP) method, for example. In the case of using a dry etching method, as an etching gas, for example, a chloride gas such as chlorine, boron chloride, silicon chloride, carbon tetrachloride, or the like; a fluoride gas such as carbon tetrafluoride, sulfur fluoride, nitrogen fluoride, or the like can be used suitably.

The insulating layer 181A is provided between the pixel electrode 111a, the pixel electrode 111b, the pixel electrode 111c, and the conductive layer 123. The top surface of the insulating layer 181A is preferably level or substantially level with the top surfaces of the pixel electrode 111a, the pixel electrode 111b, the pixel electrode 111c, and the conductive layer 123. When the top surfaces of the insulating layer 181A, the pixel electrode 111a, the pixel electrode 111b, the pixel electrode 111c, and the conductive layer 123 are level with each other, coverage with a film formed later (here, the conductive layer 116) can be improved.

Next, a conductive film 116fA is formed over the pixel electrode 111a, the pixel electrode 111b, the pixel electrode 111c, the conductive layer 123, and the insulating layer 181A, and a resist mask 190A is formed over the conductive film 116fA (FIG. 12D). The conductive film 116fA is a film to be the conductive layer 116aA, and the resist mask 190A is provided in a region overlapping with the pixel electrode 111a.

The resist mask 190A can be formed by application of a photosensitive resin (photoresist), light exposure, and development. The resist mask 190A may be formed using either a positive resist material or a negative resist material.

Then, part of the conductive film 116fA is removed with the use of the resist mask 190A as a mask to form the conductive layer 116aA. After that, the resist mask 190A is removed (FIG. 12E).

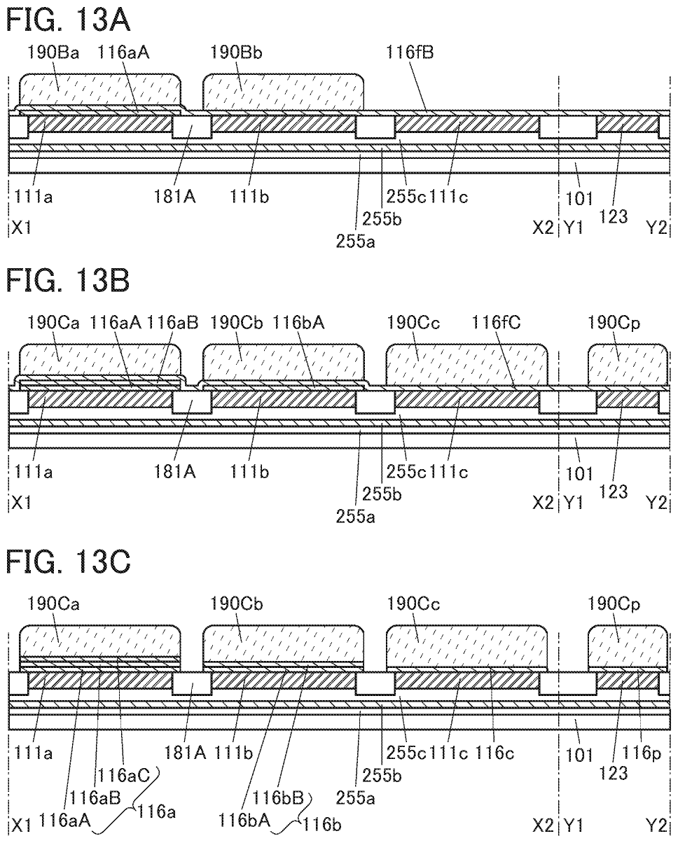

Next, a conductive film 116fB is formed over the conductive layer 116aA, the pixel electrode 111b, the pixel electrode 111c, the conductive layer 123, and the insulating layer 181A, and a resist mask 190Ba and a resist mask 190Bb are formed over the conductive film 116fB (FIG. 13A). The conductive film 116fB is a film to be the conductive layer 116aB and the conductive layer 116bA. The resist mask 190Ba is provided in a region overlapping with the pixel electrode 111a, and the resist mask 190Bb is provided in a region overlapping with the pixel electrode 111b.

Next, part of the conductive film 116fB is removed with the use of the resist mask 190Ba and the resist mask 190Bb as a mask to form the conductive layer 116aB and the conductive layer 116bA. The resist mask 190Ba and the resist mask 190Bb are removed.

Next, a conductive film 116fC is formed over the conductive layer 116aB, the conductive layer 116bA, the pixel electrode 111c, the conductive layer 123, and the insulating layer 181A, and a resist mask 190Ca, a resist mask 190Cb, a resist mask 190Cc, and a resist mask 190Cp are formed over the conductive film 116fC (FIG. 13B). The conductive film 116fC is a film to be the conductive layer 116aC, the conductive layer 116bB, the conductive layer 116c, and the conductive layer 116p. The resist mask 190Ca is provided in a region overlapping with the pixel electrode 111a, the resist mask 190Cb is provided in a region overlapping with the pixel electrode 111b, the resist mask 190Cc is provided in a region overlapping with the pixel electrode 111c, and the resist mask 190Cp is provided in a region overlapping with the conductive layer 123.

Next, part of the conductive film 116fC is removed with the use of the resist mask 190Ca, the resist mask 190Cb, the resist mask 190Cc, and the resist mask 190Cp as a mask to form the conductive layer 116aC, the conductive layer 116bB, the conductive layer 116c, and the conductive layer 116p (FIG. 13C). Thus, the conductive layer 116a which includes the conductive layer 116aA, the conductive layer 116aB, and the conductive layer 116aC stacked in this order is formed in a region overlapping with the pixel electrode 111a. The conductive layer 116b which includes the conductive layer 116bA and the conductive layer 116bB stacked in this order is formed in a region overlapping with the pixel electrode 111b.

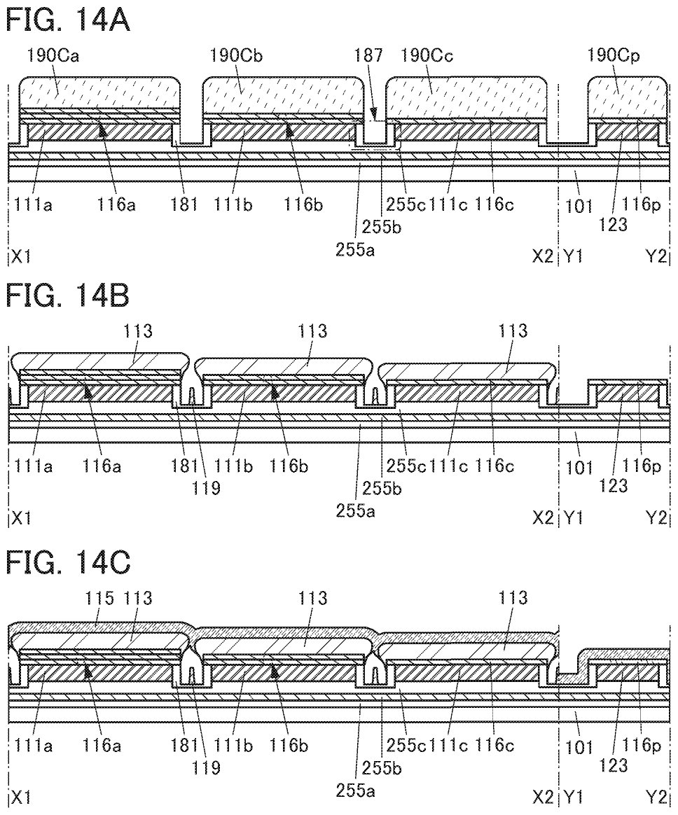

Next, part of the insulating layer 181A is removed with the use of the resist mask 190Ca, the resist mask 190Cb, the resist mask 190Cc, and the resist mask 190Cp as a mask and the insulating layer 181 including the opening 187 is formed (FIG. 14A). Then, the resist mask 190Ca, the resist mask 190Cb, the resist mask 190Cc, and the resist mask 190Cp are removed.

The opening 187 can be formed by one or both of a dry etching method and a wet etching method. In the formation of the opening 187, the angle θ1 formed between the side surface and the top surface of the insulating layer 181 preferably within the above range. The opening 187 can be suitably formed especially by an anisotropic dry etching method.

Although an example in which the opening 187 is formed with the use of the resist mask 190Ca, the resist mask 190Cb, the resist mask 190Cc, and the resist mask 190Cp as a mask is described here, one embodiment of the present invention is not limited thereto. After the conductive layer 116a, the conductive layer 116b, the conductive layer 116c, and the conductive layer 116p are formed, the resist mask 190Ca, the resist mask 190Cb, the resist mask 190Cc, and the resist mask 190Cp may be removed and the opening 187 may be formed using a resist mask separately formed. Here, the width (W1) of the opening 187 is preferably within the above range.

Then, the conductive layer 116 is preferably subjected to hydrophobic treatment. The hydrophobic treatment can change the hydrophilic properties of the subject surface to hydrophobic properties or increase the hydrophobic properties of the subject surface. The hydrophobic treatment for the conductive layer 116 can increase the adhesion between the conductive layer 116 and the EL layer 113 formed in a later step and inhibit peeling of the EL layer 113. Note that the hydrophobic treatment is not necessarily performed.

The hydrophobic treatment can be performed by fluorine modification of the conductive layer 116, for example. The fluorine modification can be performed by treatment using a gas containing fluorine, heat treatment, plasma treatment in a gas atmosphere containing fluorine, or the like. A fluorine gas can be used as the gas containing fluorine, and for example, a fluorocarbon gas can be used. As the fluorocarbon gas, a low carbon fluoride gas such as a carbon tetrafluoride (CF₄) gas, a C₄F₆ gas, a C₂F₆ gas, a C₄F₈ gas, or a C₅F₈ gas can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

Treatment using a silylation agent is performed on the surface of the conductive layer 116 after plasma treatment is performed in a gas atmosphere containing a Group 18 element such as argon, so that the surface of the conductive layer 116 can become hydrophobic. As the silylation agent, hexamethyldisilazane (HMDS), N-trimethylsilylimidazole (TMSI), or the like can be used. Alternatively, treatment using a silane coupling agent is performed on the surface of the conductive layer 116 after plasma treatment is performed in a gas atmosphere containing a Group 18 element such as argon, so that the surface of the conductive layer 116 can become hydrophobic.

Plasma treatment in a gas atmosphere containing a Group 18 element such as argon is performed on the surface of the conductive layer 116, whereby the surface of the conductive layer 116 can be damaged. Accordingly, a methyl group included in the silylation agent such as HMDS is likely to bond to the surface of the conductive layer 116. In addition, silane coupling by the silane coupling agent is likely to occur. As described above, treatment using a silylation agent or a silane coupling agent performed on the surface of the conductive layer 116 after plasma treatment in a gas atmosphere containing a Group 18 element such as argon enables the surface of the conductive layer 116 to become hydrophobic.

The treatment using the silylation agent, the silane coupling agent, or the like can be performed by application of the silylation agent, the silane coupling agent, or the like by a spin coating method or a dipping method, for example. The treatment using the silylation agent, the silane coupling agent, or the like can also be performed by forming a film containing the silylation agent, a film containing the silane coupling agent, or the like over the conductive layer 116 and the like by a gas phase method, for example. In a gas phase method, first, a material containing the silylation agent, a material containing the silane coupling agent, or the like is volatilized so that the silylation agent, the silane coupling agent, or the like is contained in the atmosphere. Then, the substrate where the conductive layer 116 or the like is formed is put in the atmosphere. Thus, a film containing the silylation agent, the silane coupling agent, or the like can be formed over the conductive layer 116, and the surface of the conductive layer 116 can be made hydrophobic.

Note that in the case where the conductive layer 116 illustrated in FIG. 1B and the like is not provided, the above hydrophobic treatment is performed on the pixel electrode 111.

Next, the EL layers 113 are formed over the conductive layer 116a, the conductive layer 116b, the conductive layer 116c, and the conductive layer 116p (FIG. 14B). At this time, the organic layer 119 may be formed in the opening 187.

As illustrated in FIG. 14B, the EL layer 113 is not formed over the conductive layer 123 in the cross-sectional view along the dashed-dotted line Y1-Y2. For example, a mask for specifying a formation area of the EL layer 113 (also referred to as an area mask or a rough metal mask to distinguish from a fine metal mask) is used, so that the EL layer 113 can be formed only in a desired region.

The EL layer 113 is preferably formed by a method providing low coverage. The EL layer 113 can be formed by an evaporation method, specifically a vacuum evaporation method, for example. The EL layer 113 may be formed by a transfer method, a printing method, an inkjet method, a coating method, or the like.

As illustrated in FIG. 14B, a plurality of island-shaped EL layers 113 can be formed without using a fine metal mask. In adjacent subpixels, the EL layers 113 can be inhibited from being in contact with each other. Accordingly, generation of leakage current between subpixels can be inhibited. Accordingly, degradation of the display quality of the display device can be inhibited. In addition, the display device can have both high resolution and high display quality.

As described above, when the island-shaped EL layer 113 is formed using the opening 187 formed by a photolithography method, the distance between two adjacent EL layers 113 can be shortened. The distance between the island-shaped EL layers 113 is shortened in this manner, whereby the display device can achieve high resolution and a high aperture ratio.

Next, the common electrode 115 is formed over the EL layer 113 and the conductive layer 116p (FIG. 14C). The common electrode 115 is preferably formed by a method providing higher coverage than formation of the EL layer 113. The common electrode 115 can be formed by a sputtering method, for example. Alternatively, a film formed by an evaporation method and a film formed by a sputtering method may be stacked.

Next, the protective layer 131 is formed over the common electrode 115, and the coloring layer 132R, the coloring layer 132G, and the coloring layer 132B are formed over the protective layer 131. In addition, the substrate 120 is attached onto the protective layer 131 and the coloring layer 132 with the resin layer 122, whereby the display device can be manufactured (FIG. 6).

The protective layer 131 can be formed by a vacuum evaporation method, a sputtering method, a CVD method, or an ALD method.

As described above, in the method for manufacturing the display device of this embodiment, the island-shaped EL layer 113 is formed without using a fine metal mask. Thus, the size of the EL layer 113 can be made smaller than the size of an EL layer formed using a fine metal mask. Accordingly, a high-resolution display device or a display device with a high aperture ratio, which has been difficult to achieve, can be manufactured. Furthermore, even when the resolution or the aperture ratio is high and the distance between subpixels is extremely short, contact between the island-shaped EL layers 113 can be inhibited in adjacent subpixels. Accordingly, generation of leakage current between subpixels can be inhibited. Accordingly, degradation of the display quality of the display device can be inhibited. In addition, both the high resolution and high display quality of the display device can be achieved.

This embodiment can be combined with the other embodiments as appropriate.

### Embodiment 2

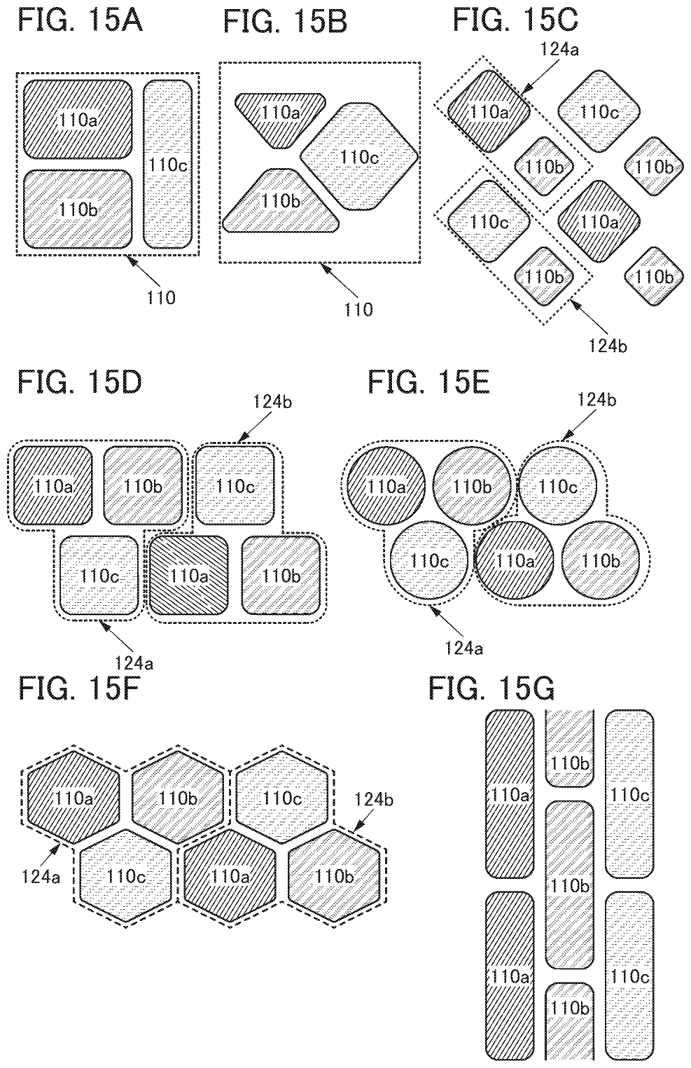

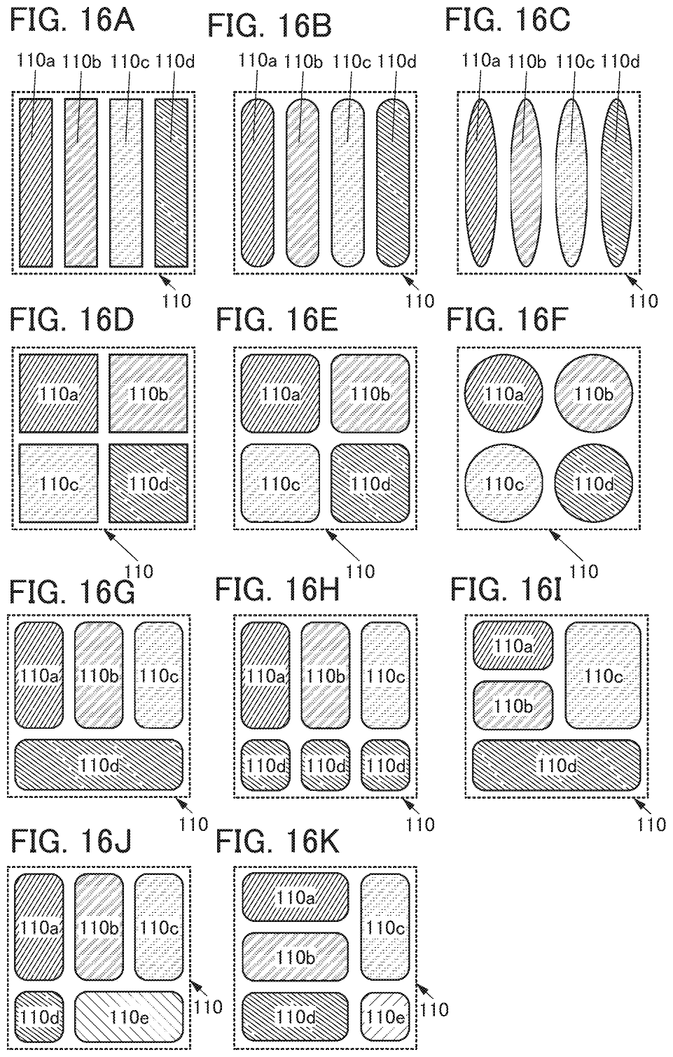

In this embodiment, display devices of one embodiment of the present invention are described with reference to FIG. 15 and FIG. 16.

### [Pixel Layout]

In this embodiment, pixel layouts different from the layout in FIG. 1A will be mainly described. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region.

Examples of a top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in a diagram and circuits may be placed outside the subpixels.

The pixel 110 illustrated in FIG. 15A employs S-stripe arrangement. The pixel 110 illustrated in FIG. 15A is composed of three subpixels: the subpixel 110a, the subpixel 110b, and the subpixel 110c.

The pixel 110 illustrated in FIG. 15B includes the subpixel 110a and the subpixel 110b whose top surface shape is a rough trapezoid or a rough triangle with rounded corners and the subpixel 110c whose top surface shape is a rough tetragon or a rough hexagon with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

Pixels 124a and 124b illustrated in FIG. 15C employ PenTile arrangement. FIG. 15C illustrates an example where the pixels 124a including the subpixel 110a and the subpixel 110b and the pixels 124b including the subpixel 110b and the subpixel 110c are alternately arranged.

The pixels 124a and 124b illustrated in FIG. 15D to FIG. 15F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 15D illustrates an example where a top surface shape of each subpixel is a rough tetragon with rounded corners, FIG. 15E illustrates an example where a top surface shape of each subpixel is a circle, and FIG. 15F illustrates an example where a top surface shape of each subpixel is a rough hexagon with rounded corners.

FIG. 15G illustrates an example where subpixels of different colors are arranged in a zigzag manner. Specifically, the positions of the top sides of two subpixels arranged in the row direction (e.g., the subpixel 110a and the subpixel 110b or the subpixel 110b and the subpixel 110c) are not aligned in a top view.

For example, in each pixel illustrated in FIG. 15A to FIG. 15G, it is preferable that the subpixel 110a be a subpixel R exhibiting red light, the subpixel 110b be a subpixel G exhibiting green light, and the subpixel 110c be a subpixel B exhibiting blue light. Note that the structure of the subpixels is not limited to this, and the colors and arrangement order of the subpixels can be determined as appropriate. For example, the subpixel 110b may be the subpixel R exhibiting red light and the subpixel 110a may be the subpixel G exhibiting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. In the top view, the outline of an end portion of the opening 187 may be a polygonal shape with rounded corners, an elliptical shape, a circular shape, or the like, for example.

In the method for manufacturing the display device of one embodiment of the present invention, the island-shaped EL layers 113 are formed owing to the steps due to the openings 187. Thus, in a top view, the top surface shape of the EL layer is not aligned with the outline of the opening 187 in some cases. As a result, the top surface of the EL layer may have a polygonal shape with rounded corners, an elliptical shape, a circular shape, or the like, for example.

As illustrated in FIG. 16A to FIG. 161, the pixel can include four types of subpixels.

The pixels 110 illustrated in FIG. 16A to FIG. 16C employ stripe arrangement.

FIG. 16A illustrates an example where each subpixel has a rectangular top surface shape, FIG. 16B illustrates an example where each subpixel has a top surface shape formed by combining two half circles and a rectangle, and FIG. 16C illustrates an example where each subpixel has an elliptical top surface shape.

The pixels 110 illustrated in FIG. 16D to FIG. 16F employ matrix arrangement.

FIG. 16D illustrates an example where each subpixel has a square top surface shape, FIG. 16E illustrates an example where each subpixel has a rough square top surface shape with rounded corners, and FIG. 16F illustrates an example where each subpixel has a circular top surface shape.

FIG. 16G and FIG. 16H each illustrate an example where one pixel 110 is composed of two rows and three columns.

The pixel 110 illustrated in FIG. 16G includes three subpixels (the subpixels 110a, 110b, and 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 16H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 16H enables efficient removal of dust and the like that would be produced in the manufacturing process. Thus, a display device with high display quality can be provided.

FIG. 16I illustrates an example where one pixel 110 is composed of three rows and two columns.

The pixel 110 illustrated in FIG. 16I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 16A to FIG. 16I are each composed of four subpixels: the subpixels 110a, 110b, 110c, and 110d.

The subpixels 110a, 110b, 110c, and 110d can include light-emitting devices with different emission colors. The subpixels 110a, 110b, 110c, and 110d can be subpixels of four colors of R, G, B, and white (W), subpixels of four colors of R, G, B, and Y, or subpixels of R, G, B, and infrared light (IR), for example.

In the pixels 110 illustrated in FIG. 16A to FIG. 16I, it is preferable that the subpixel 110a be a subpixel exhibiting red light, the subpixel 110b be a subpixel exhibiting green light, the subpixel 110c be a subpixel exhibiting blue light, and the subpixel 110d be any of a subpixel emitting white light, a subpixel emitting yellow light, and a subpixel exhibiting near-infrared light, for example. In the case of such a structure, stripe arrangement is employed as the layout of R, G, and B in the pixels 110 illustrated in FIG. 16G and FIG. 16H, leading to higher display quality. In addition, what is called S-stripe arrangement is employed as the layout of R, G, and B in the pixel 110 illustrated in FIG. 16I, leading to higher display quality.

As illustrated in FIG. 16J and FIG. 16K, the pixel can include five types of subpixels. Examples of subpixels of five colors include subpixels of five colors of R, G, B, Y, and W.

FIG. 16J illustrates an example where one pixel 110 is composed of two rows and three columns.

The pixel 110 illustrated in FIG. 16J includes three subpixels (the subpixels 110a, 110b, and 110c) in the upper row (first row) and two subpixels (the subpixels 110d and 110e) in the lower row (second row). In other words, the pixel 110 includes the subpixels 110a and 110d in the left column (first column), the subpixel 110b in the center column (second column), the subpixel 110c in the right column (third column), and the subpixel 110e across the second and third columns.

FIG. 16K illustrates an example where one pixel 110 is composed of three rows and two columns.

The pixel 110 illustrated in FIG. 16K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 110 includes the subpixels 110a, 110b, and 110d in the left column (first column), and the subpixels 110c and 110e in the right column (second column).

As described above, the pixel composed of the subpixels each including the light-emitting device can employ any of a variety of layouts in the display device of one embodiment of the present invention.

This embodiment can be combined with the other embodiments as appropriate.

### Embodiment 3

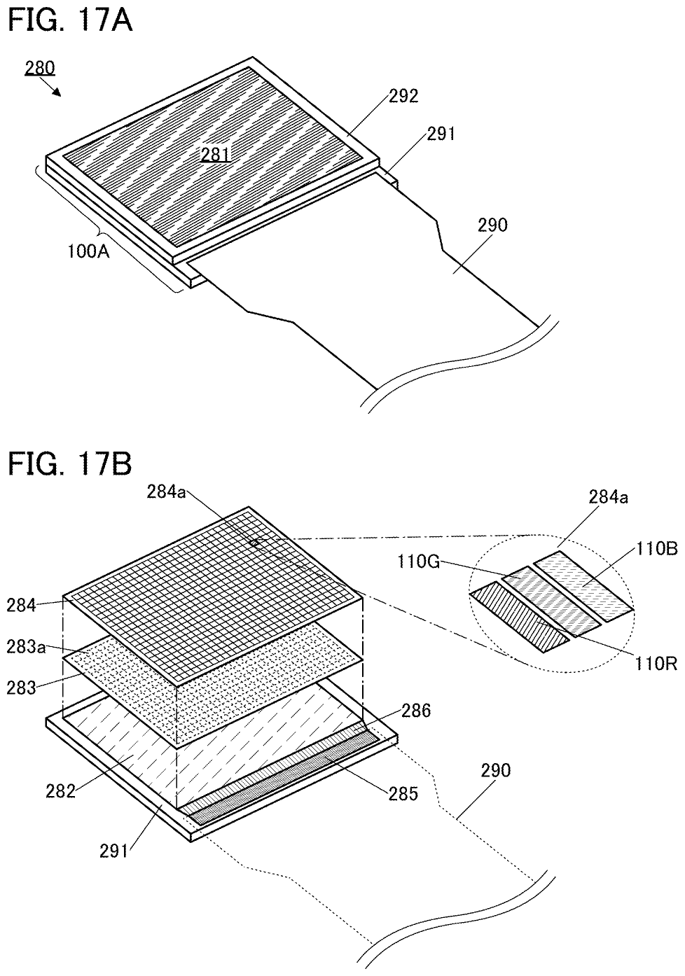

In this embodiment, a display device of one embodiment of the present invention is described with reference to FIG. 17 to FIG. 26.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display device of this embodiment can be a high-definition display device or a large-sized display device. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Module]

FIG. 17A illustrates a perspective view of a display module 280. The display module 280 includes a display device 100A and an FPC 290. Note that the display device included in the display module 280 is not limited to the display device 100A and may be any of a display device 100B to a display device 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 17B illustrates a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 17B. The pixel 284a can employ any of the structures described in the above embodiments. FIG. 17B illustrates an example in which a structure similar to that of the pixel 110 illustrated in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-definition display portion 281 included in the display module 280 are not seen even when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### [Display Device 100A]

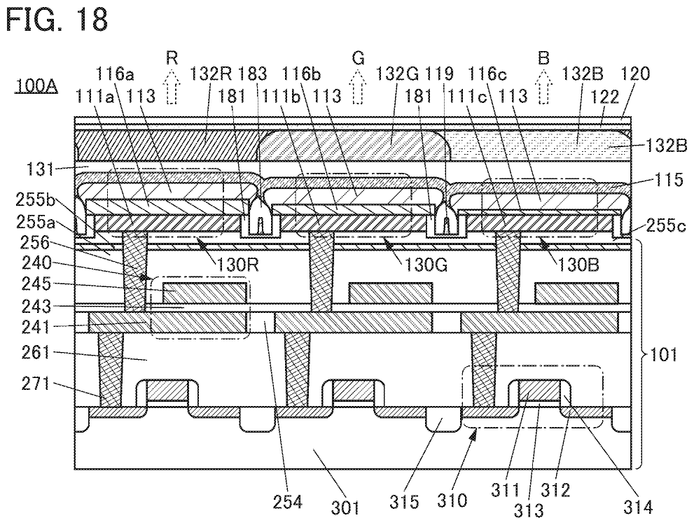

The display device 100A illustrated in FIG. 18A includes a substrate 301, a light-emitting device 130R, a light-emitting device 130G, a light-emitting device 130B, the coloring layer 132R, the coloring layer 132G, the coloring layer 132B, a capacitor 240, and a transistor 310.

A subpixel 110R illustrated in FIG. 17B includes the light-emitting device 130R and the coloring layer 132R, a subpixel 110G includes the light-emitting device 130G and the coloring layer 132G, and a subpixel 110B includes the light-emitting device 130B and the coloring layer 132B. In the subpixel 110R, light emitted by the light-emitting device 130R is extracted as red light to the outside of the display device 100A through the coloring layer 132R. Similarly, in the subpixel 110G, light emitted by the light-emitting device 130G is extracted as green light to the outside of the display device 100A through the coloring layer 132G. In the subpixel 110B, light emitted by the light-emitting device 130B is extracted as blue light to the outside of the display device 100A through the coloring layer 132B.

The substrate 301 corresponds to the substrate 291 in FIG. 17A and FIG. 17B. A stacked-layer structure from the substrate 301 to the insulating layer 255c corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101 including transistors. The conductive layer can be referred to as a guard ring. By providing the conductive layer, elements such as a transistor and a light-emitting device can be inhibited from being broken by high voltage application due to ESD (electronic discharge) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting device 130R, the light-emitting device 130G, and the light-emitting device 130B are provided over the insulating layer 255c. FIG. 18A illustrates an example in which the light-emitting device 130R, the light-emitting device 130G, and the light-emitting device 130B each have the stacked-layer structure illustrated in FIG. 1B. The insulating layer 181 is provided in a region between adjacent light-emitting devices.

The pixel electrode 111a, the pixel electrode 111b, and the pixel electrode 111c are each electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. The top surface of the insulating layer 255c and the top surface of the plug 256 are level or substantially level with each other. A variety of conductive materials can be used for the plugs. FIG. 18A and the like illustrate an example in which the pixel electrode has a two-layer structure of a reflective electrode and a transparent electrode over the reflective electrode.

The protective layer 131 is provided over the light-emitting device 130R, the light-emitting device 130G, and the light-emitting device 130B. The substrate 120 is attached onto the protective layer 131 with the resin layer 122. Embodiment 1 can be referred to for the details of the light-emitting devices and the components thereover up to the substrate 120. The substrate 120 corresponds to the substrate 292 in FIG. 17A.

### [Display Device 100B]

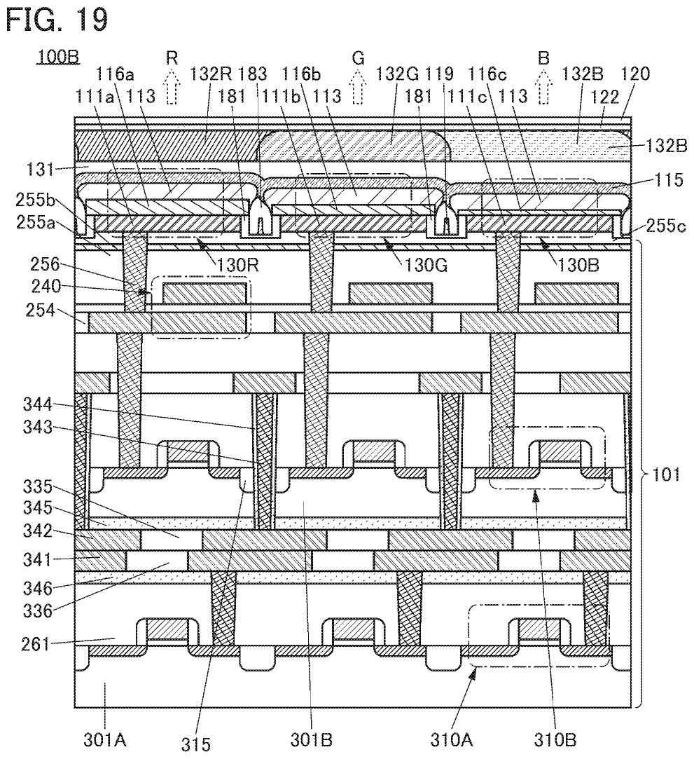

The display device 100B illustrated in FIG. 19 has a structure where a transistor 310A and a transistor 310B in each of which a channel is formed in a semiconductor substrate are stacked. Note that in the description of the display device below, portions similar to those of the above-described display device are not described in some cases.

In the display device 100B, a substrate 301B provided with the transistor 310B, the capacitor 240, and the light-emitting devices is attached to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used as the protective layer 131 or an insulating layer 332 can be used.

The substrate 301B is provided with a plug 343 that penetrates the substrate 301B and the insulating layer 345. An insulating layer 344 is preferably provided to cover a side surface of the plug 343. The insulating layer 344 is an insulating layer functioning as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Meanwhile, a conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be attached to each other favorably.

The conductive layer 341 and the conductive layer 342 are preferably formed using the same conductive material. For the conductive layer 341 and the conductive layer 342, for example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Device 100C]

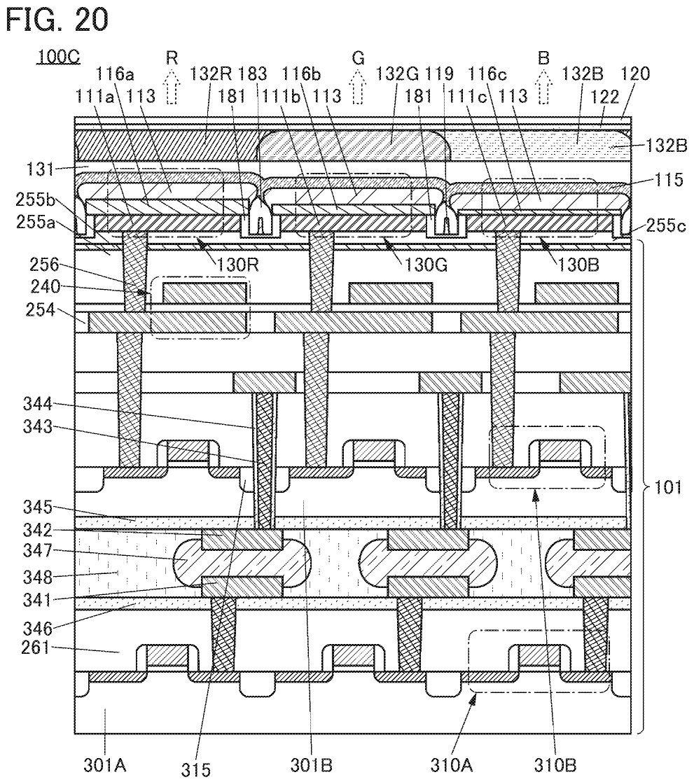

The display device 100C illustrated in FIG. 20 has a structure in which the conductive layer 341 and the conductive layer 342 are bonded to each other through a bump 347.

As illustrated in FIG. 20, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 100D]

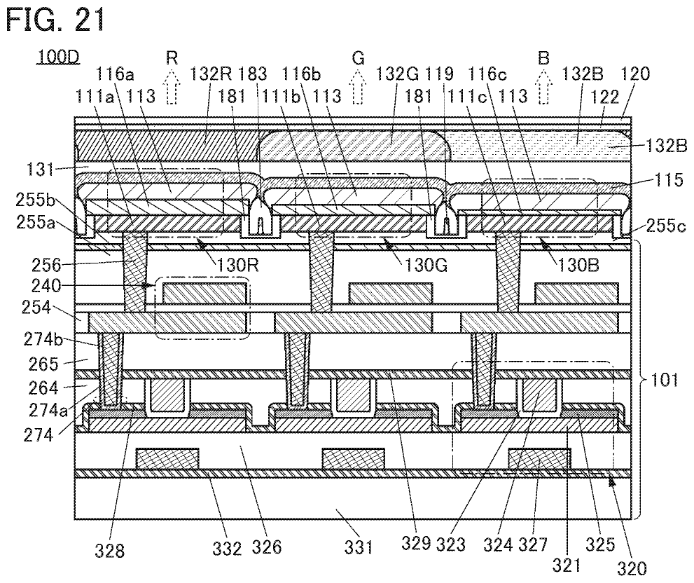

The display device 100D illustrated in FIG. 21 differs from the display device 100A mainly in a structure of a transistor.

A transistor 320 is a transistor (OS transistor) that includes a metal oxide (also referred to as an oxide semiconductor) having semiconductor characteristics in its semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 17A and FIG. 17B. A stacked-layer structure from the substrate 331 to the insulating layer 255c corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide film having semiconductor characteristics (oxide semiconductor film) is preferably used as the semiconductor layer 321. The pair of conductive layers 325 is provided over and in contact with the semiconductor layer 321 and functions as a source electrode and a drain electrode.

An insulating layer 328 is provided to cover the top surfaces and side surfaces of the pair of conductive layers 325, side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so as to be level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering a side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Device 100E]

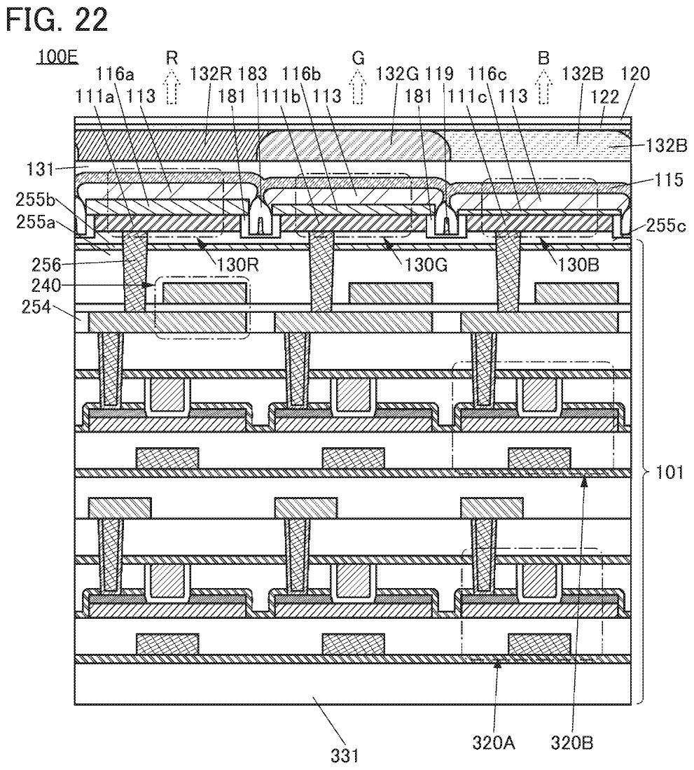

A display device 100E illustrated in FIG. 22 has a structure in which a transistor 320A and a transistor 320B each including an oxide semiconductor in a semiconductor where a channel is formed are stacked.

The display device 100D can be referred to for the transistor 320A, the transistor 320B, and the components around them.

Although the structure in which two transistors including an oxide semiconductor are stacked is described, the present invention is not limited thereto. For example, three or more transistors may be stacked.

### [Display Device 100F]

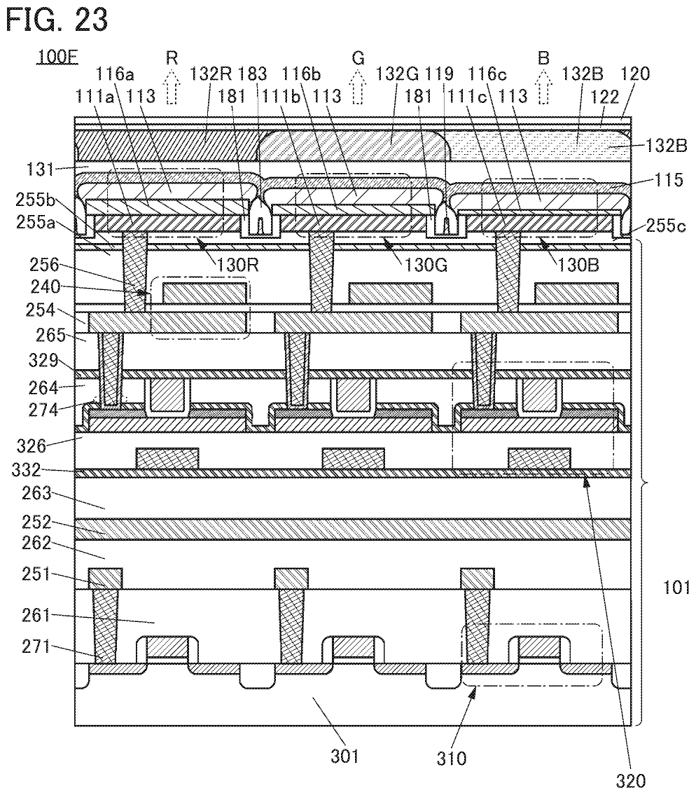

The display device 100F illustrated in FIG. 23 has a structure in which the transistor 310 having a channel formed in the substrate 301 and the transistor 320 containing a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display device can be downsized as compared to the case where the driver circuit is provided around a display region.

### [Display Device 100G]

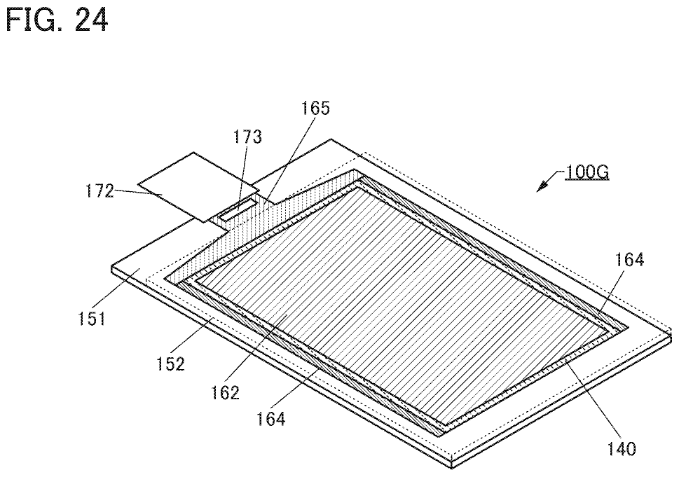

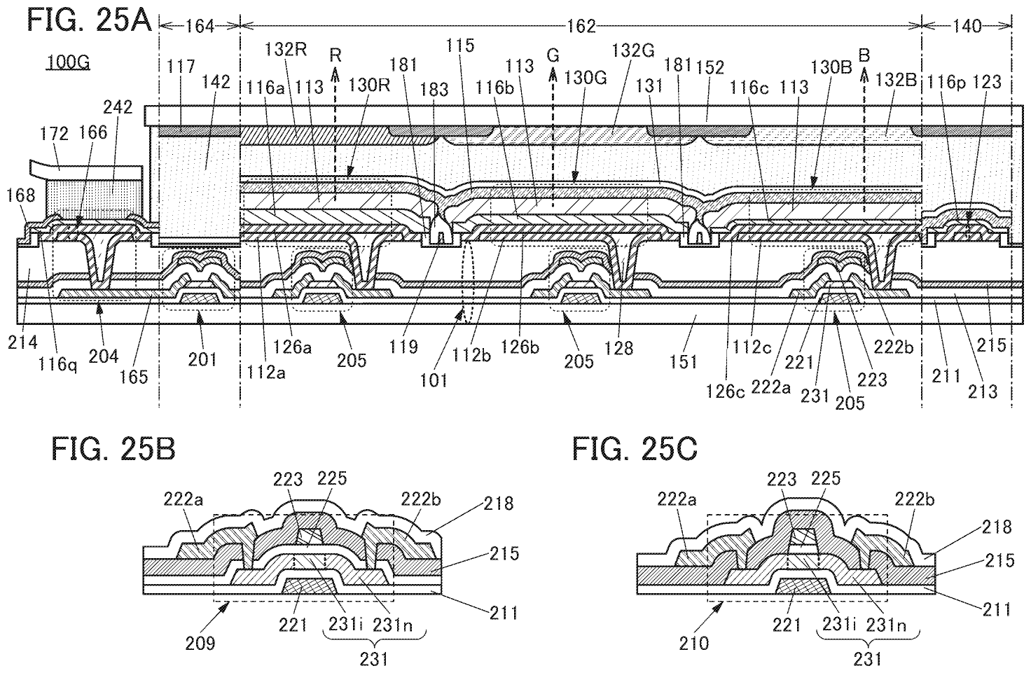

FIG. 24 is a perspective view of a display device 100G, and FIG. 25A is a cross-sectional view of the display device 100G.

In the display device 100G, a substrate 152 and a substrate 151 are attached to each other. In FIG. 24, the substrate 152 is denoted by a dashed line.

The display device 100G includes a display portion 162, the connection portion 140, a circuit 164, a wiring 165, and the like. FIG. 24 illustrates an example in which an IC 173 and an FPC 172 are mounted on the display device 100G. Thus, the structure illustrated in FIG. 24 can also be regarded as a display module including the display device 100G, the IC (integrated circuit), and the FPC.

The connection portion 140 is provided outside the display portion 162. The connection portion 140 can be provided along one or more sides of the display portion 162. The number of the connection portions 140 can be one or more. FIG. 24 illustrates an example in which the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 24 illustrates an example in which the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display device 100G and the display module are not necessarily provided with an IC. The IC may be mounted on the FPC by a COF method or the like.

FIG. 25A illustrates an example of cross sections of part of a region including the FPC 172, part of the circuit 164, part of the display portion 162, part of the connection portion 140, and part of a region including an end portion of the display device 100G.

The display device 100G illustrated in FIG. 25A includes a transistor 201, a transistor 205, the light-emitting device 130R emitting red light, the light-emitting device 130G emitting green light, the light-emitting device 130B, the coloring layer 132R transmitting red light, the coloring layer 132G transmitting green light, the coloring layer 132B transmitting blue light, and the like between the substrate 151 and the substrate 152.

The light-emitting device 130R, the light-emitting device 130G, and the light-emitting device 130B can have the structure described in Embodiment 1 or the like except for the structure of the pixel electrode.

The light-emitting device 130R includes a conductive layer 112a and a conductive layer 126a over the conductive layer 112a. The conductive layer 112a and the conductive layer 126a correspond to the pixel electrode 111a described in Embodiment 1.

The light-emitting device 130G includes a conductive layer 112b and a conductive layer 126b over the conductive layer 112b.

The light-emitting device 130B includes a conductive layer 112c and a conductive layer 126c over the conductive layer 112c.

The conductive layer 112a is connected to a conductive layer 222b included in the transistor 205 through an opening provided in an insulating layer 214. An end portion of the conductive layer 126a is positioned outward from an end portion of the conductive layer 112a. The conductive layer 116a is provided over the conductive layer 126a. The conductive layer 116a functions as an optical adjustment layer. For example, a conductive layer having a property of reflecting visible light can be used for the conductive layer 112a and the conductive layer 126a, and a conductive layer having a property of transmitting visible light can be used for the conductive layer 116a.

Detailed description of the conductive layer 112b, the conductive layer 126b, and the conductive layer 116b of the light-emitting device 130G and the conductive layer 112c and the conductive layers 126c and 116c of the light-emitting device 130B is omitted because these conductive layers are similar to the conductive layer 112a and the conductive layers 126a and 116a of the light-emitting device 130R.

Depressed portions are formed in the conductive layer 112a, the conductive layer 112b, and the conductive layer 112c to cover the openings provided in the insulating layer 214. A layer 128 is embedded in the depression portions.

The layer 128 has a planarization function for the depressed portions of the conductive layer 112a, the conductive layer 112b, and the conductive layer 112c. The conductive layer 126a, the conductive layer 126b, and the conductive layer 126c electrically connected to the conductive layer 112a, the conductive layer 112b, and the conductive layer 112c, respectively, are provided over the conductive layer 112a, the conductive layer 112b, and the conductive layer 112c and the layer 128. Thus, regions overlapping with the depressed portions of the conductive layer 112a, the conductive layer 112b, and the conductive layer 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the protective layer 131 can be used, for example.

The protective layer 131 is provided over the light-emitting device 130R, the light-emitting device 130G, and the light-emitting device 130B. The protective layer 131 and the substrate 152 are bonded to each other with an adhesive layer 142. The substrate 152 is provided with a light-blocking layer 117 and the coloring layer 132R, the coloring layer 132G, and the coloring layer 132B. A solid sealing structure, a hollow sealing structure, or the like can be employed to seal the light-emitting device 130. In FIG. 25A, a solid sealing structure is employed in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting device. The space may be filled with a resin different from that of the frame-like adhesive layer 142.

The conductive layer 123 is provided over the insulating layer 214 in the connection portion 140. The conductive layer 123 can have a stacked-layer structure of a conductive film obtained by processing the same conductive film as the conductive layer 112a, the conductive layer 112b, and the conductive layer 112c, and a conductive film obtained by processing the same conductive film as the conductive layer 126a, the conductive layer 126b, and the conductive layer 126c. The end portion of the conductive layer 123 is covered with the insulating layer 181. The conductive layer 116p is provided over the conductive layer 123, and the common electrode 115 is provided over the conductive layer 116p. The conductive layer 123 and the common electrode 115 are electrically connected to each other through the conductive layer 116p. Note that the conductive layer 116p is not necessarily formed in the connection portion 140. In this case, the conductive layer 123 and the common electrode 115 are in direct contact with each other to be electrically connected to each other.

The display device 100G has a top-emission structure. Light emitted by the light-emitting device is emitted toward the substrate 152 side. For the substrate 152, a material having a high visible-light-transmitting property is preferably used. The pixel electrode contains a material reflecting visible light, and the counter electrode (the common electrode 115) contains a material transmitting visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers that cover the transistors. This allows the insulating layer to function as a barrier layer. Such a structure can effectively inhibit diffusion of impurities into the transistors from the outside and improve the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a depressed portion can be prevented from being formed in the insulating layer 214 in processing the conductive layer 112a or the conductive layer 126a. Alternatively, a depressed portion may be provided in the insulating layer 214 in processing the conductive layer 112a or the conductive layer 126a.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or bottom-gate transistor structure may be employed. Alternatively, gates may be provided above and below the semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal semiconductor (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer of the transistor preferably includes a metal oxide having semiconductor characteristics (an oxide semiconductor). That is, a transistor including a metal oxide in its channel formation region (hereinafter, also referred to as an OS transistor) is preferably used for the display device of this embodiment.

As the oxide semiconductor having crystallinity, a CAAC (c-axis aligned crystalline)-OS, an nc (nanocrystalline)-OS, and the like are given.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the display device and a reduction in component cost and mounting cost.

An OS transistor has much higher field-effect mobility than a transistor using amorphous silicon. In addition, an OS transistor has extremely low leakage current between a source and a drain in an off state (hereinafter, also referred to as off-state current), and charge accumulated in a capacitor that is connected in series to the transistor can be retained for a long period. Furthermore, the power consumption of the display device can be reduced with the OS transistor.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current with respect to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, with use of an OS transistor as a driving transistor, current can be made flow stably through the light-emitting device, for example, even when a variation in current-voltage characteristics of the EL device occurs. In other words, when the OS transistor operates in the saturation region, the source-drain current hardly changes with an increase in the source-drain voltage; hence, the emission luminance of the light-emitting device can be stable.

As described above, with use of an OS transistor as the driving transistor included in the pixel circuit, it is possible to achieve “inhibition of black floating”, “increase in emission luminance”, “increase in the number of gray levels”, “inhibition of variation in light-emitting devices”, and the like.

The metal oxide contained in the semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the content ratio of each element is as follows; Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where the content ratio of each element is as follows; Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where the content ratio of each element is as follows; Ga is greater than 0.1 and less than or equal to 2 and Zn is greater than 0.1 and less than or equal to 2 with In being 1.

The transistors included in the circuit 164 and the transistors included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. Note that a structure in which the OS transistor is used as a transistor functioning as a switch controlling conduction or non-conduction between wirings, and the LTPS transistor is used as a transistor controlling current, for example, is more preferably employed.

For example, one transistor included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

In contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML (metal maskless) structure. This structure can significantly reduce the leakage current that might flow through a transistor, and the leakage current that might flow between adjacent light-emitting devices (also referred to as lateral leakage current, side leakage current, or the like). With the structure, a viewer can observe any one or more of the image crispness, the image sharpness, a high chroma, and a high contrast ratio in an image displayed on the display device. Note that when the leakage current that might flow through a transistor and the lateral leakage current between light-emitting devices are extremely low, light leakage or the like (what is called black blurring) that might occur in black display can be reduced as much as possible.

FIG. 25B and FIG. 25C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 25B illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 25C, the insulating layer 225 overlaps with the channel formation region 231i of the semiconductor layer 231 and does not overlap with the low-resistance regions 231n. The structure illustrated in FIG. 25C can be fabricated by processing the insulating layer 225 using the conductive layer 223 as a mask, for example. In FIG. 25C, the insulating layer 215 is provided to cover the insulating layer 225 and the conductive layer 223, and the conductive layer 222a and the conductive layer 222b are connected to the low-resistance regions 23 In through the openings in the insulating layer 215.

A connection portion 204 is provided in a region of the substrate 151 not overlapping with the substrate 152. In the connection portion 204, the wiring 165 is electrically connected to the FPC 172 through a conductive layer 166, a conductive layer 116q, and a connection layer 242. The conductive layer 166 can have a stacked-layer structure of a conductive film obtained by processing the same conductive film as the conductive layer 112a, the conductive layer 112b, and the conductive layer 112c and a conductive film obtained by processing the same conductive film as the conductive layer 126a, the conductive layer 126b, and the conductive layer 126c. The conductive layer 116q can be formed by processing the same conductive film as any of the conductive layer 116a, the conductive layer 116b, and the conductive layer 116c. For example, the conductive layer 116q can be formed in the same step as the conductive layer 116c, and as illustrated in FIG. 25A, the thickness of the conductive layer 116q can be equal or substantially equal to the thickness of the conductive layer 116c.

In the connection portion 204, an end portion of the conductive layer 116p is preferably covered with an insulating layer 168 in order to prevent the surface of the conductive layer 116p from being exposed. When the end portion of the conductive layer 116p is covered with the insulating layer 168, defects such as oxidation of the conductive layer 116p and a short circuit can be inhibited. Note that the conductive layer 116q is not necessarily provided. In the case where the conductive layer 116q is not provided, an end portion of the conductive layer 166 is covered with the insulating layer 168. The conductive layer 166 may be electrically connected to the FPC 172 through the connection layer 242.

The light-blocking layer 117 is preferably provided on the surface of the substrate 152 on the substrate 151 side. The light-blocking layer 117 can be provided between adjacent light-emitting devices, in the connection portion 140, and in the circuit 164, for example. A variety of optical members can be arranged on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### [Display Device 100H]

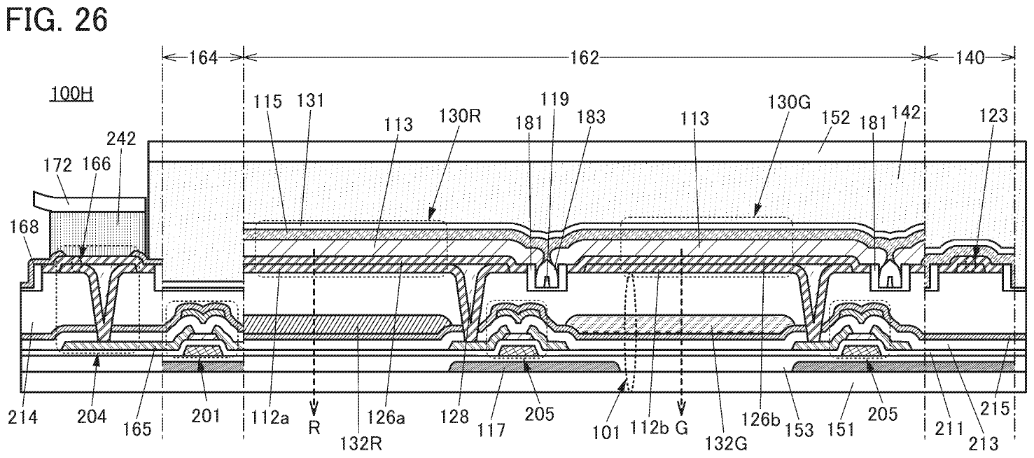

A display device 100H illustrated in FIG. 26 is different from the display device 100G mainly in being a bottom-emission display device.

Light emitted by the light-emitting device is emitted toward the substrate 151 side. For the substrate 151, a material having a high visible-light-transmitting property is preferably used. In contrast, there is no limitation on the light-transmitting property of a material used for the substrate 152.

The light-blocking layer 117 is preferably formed between the substrate 151 and the transistor 201 and between the substrate 151 and the transistor 205. FIG. 26 illustrates an example in which the light-blocking layer 117 is provided over the substrate 151, an insulating layer 153 is provided over the light-blocking layer 117, and the transistor 201 and the transistor 205 and the like are provided over the insulating layer 153.

A material having a high visible-light-transmitting property is used for each of the conductive layer 112a, the conductive layer 112b, the conductive layer 126a, and the conductive layer 126b. A material reflecting visible light is preferably used for the common electrode 115.

Although FIG. 25A and FIG. 26 illustrate an example in which the top surface of the layer 128 includes a flat portion, the shape of the layer 128 is not particularly limited. The top surface of the layer 128 can have a shape in which its center and the vicinity thereof are depressed, i.e., a shape including a concave surface, in a cross-sectional view. Alternatively, the top surface of the layer 128 can have a shape in which its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 112a may be equal to or substantially equal to each other, or may be different from each other. For example, the level of the top surface of the layer 128 may be either lower or higher than the level of the top surface of the conductive layer 112a.

This embodiment can be combined with the other embodiments as appropriate.

### Embodiment 4

In this embodiment, light-emitting devices that can be used for the display device of one embodiment of the present invention will be described.

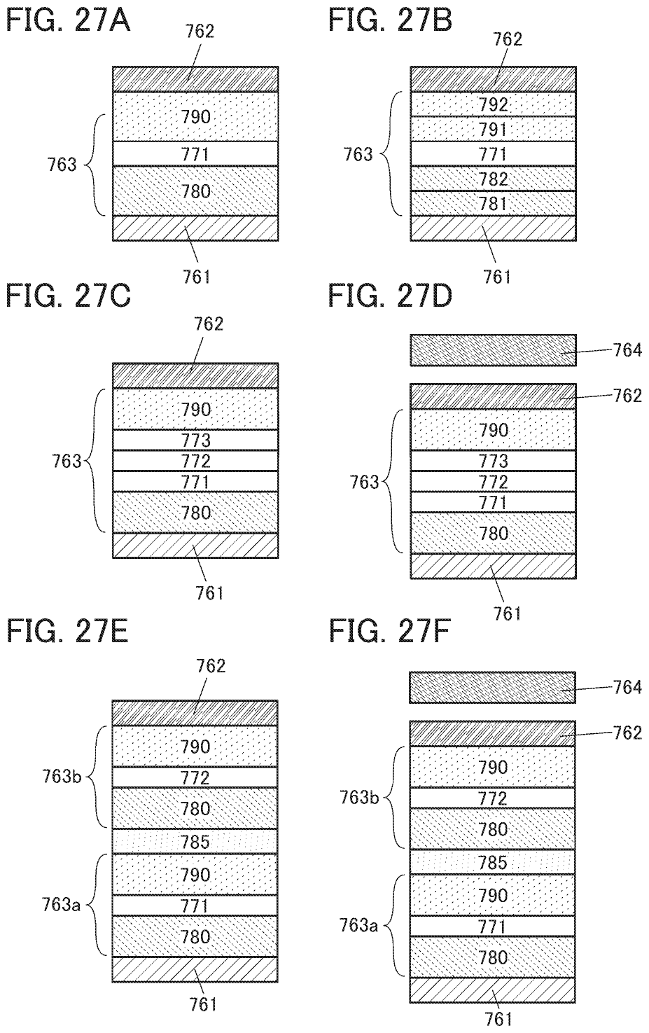

As illustrated in FIG. 27A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a material with a high hole-injection property (a hole-injection layer), a layer containing a material with a high hole-transport property (a hole-transport layer), and a layer containing a material with a high electron-blocking property (an electron-blocking layer). Furthermore, the layer 790 includes one or more of a layer containing a material with a high electron-injection property (an electron-injection layer), a layer containing a material with a high electron-transport property (an electron-transport layer), and a layer containing a material with a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between a pair of electrodes, can function as a single light-emitting unit, and the structure in FIG. 27A is referred to as a single structure in this specification.

FIG. 27B is a variation example of the EL layer 763 included in the light-emitting device illustrated in FIG. 27A. Specifically, the light-emitting device illustrated in FIG. 27B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of the recombination of carriers in the light-emitting layer 771 can be increased.

Note that structures in which a plurality of light-emitting layers (light-emitting layers 771, 772, and 773) are provided between the layer 780 and the layer 790 as illustrated in FIG. 27C and FIG. 27D are variations of the single structure. Although FIG. 27C and FIG. 27D illustrate the examples where three light-emitting layers are included, the light-emitting device having a single structure may include two or four or more light-emitting layers. In addition, the light-emitting device having a single structure may include a buffer layer between two light-emitting layers.

A structure where a plurality of light-emitting units (a light-emitting unit 763a and a light-emitting unit 763b) are connected in series with a charge-generation layer 785 therebetween as illustrated in FIG. 27E and FIG. 27F is referred to as a tandem structure in this specification. The tandem structure may be referred to as a stack structure. The tandem structure enables a light-emitting device capable of high-luminance light emission. Furthermore, the tandem structure reduces the amount of current needed for obtaining the same luminance as compared with a single structure, and thus can improve the reliability. Note that the charge-generation layer is also referred to as an intermediate layer.

Note that FIG. 27D and FIG. 27F illustrate examples where the display device includes a layer 764 overlapping with the light-emitting device. FIG. 27D illustrates an example in which the layer 764 overlaps with the light-emitting device illustrated in FIG. 27C, and FIG. 27F illustrates an example in which the layer 764 overlaps with the light-emitting device illustrated in FIG. 27E.

One or both of a color conversion layer and a color filter (coloring layer) can be used as the layer 764.

In FIG. 27C and FIG. 27D, light-emitting substances that emit light of the same color, or moreover, the same light-emitting substance may be used for the light-emitting layer 771, the light-emitting layer 772, and the light-emitting layer 773. For example, a light-emitting substance emitting blue light may be used for the light-emitting layer 771, the light-emitting layer 772, and the light-emitting layer 773. In a subpixel that exhibits blue light, blue light emitted from the light-emitting device can be extracted. In a subpixel that exhibits red light and a subpixel that exhibits green light, by providing a color conversion layer as the layer 764 illustrated in FIG. 27D, blue light emitted from the light-emitting device can be converted into light with a longer wavelength, and red light or green light can be extracted.

Alternatively, light-emitting substances emitting light of different colors may be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting device having a single structure preferably includes a light-emitting layer containing a light-emitting substance emitting blue light and a light-emitting layer containing a light-emitting substance emitting visible light with a longer wavelength than blue light, for example.

In the case where the light-emitting device having a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB or RBG from an anode side, for example. In that case, a buffer layer may be provided between R and G or between R and B.

For example, in the case where the light-emitting device having a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

A color filter (also referred to as a coloring layer) may be provided as the layer 764 illustrated in FIG. 27D. When white light passes through the coloring filter, light of a desired color can be obtained.

The light-emitting device emitting white light preferably contains two or more kinds of light-emitting substances. To obtain white light emission, two or more kinds of light-emitting substances are selected such that they emit light of complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

In FIG. 27E and FIG. 27F, light-emitting substances that emit light of the same color, or moreover, the same light-emitting substance may be used for the light-emitting layer 771 and the light-emitting layer 772.

For example, in light-emitting devices included in subpixels exhibiting light of different colors, a light-emitting substance that emits blue light can be used for each of the light-emitting layer 771 and the light-emitting layer 772. In a subpixel that exhibits blue light, blue light emitted from the light-emitting device can be extracted. In the subpixel that exhibits red light and the subpixel that exhibits green light, by providing a color conversion layer as the layer 764 illustrated in FIG. 27F, blue light emitted from the light-emitting device can be converted into light with a longer wavelength, and red light or green light can be extracted.

Light-emitting substances whose emission colors are different from each other may be used for the light-emitting layer 771 and the light-emitting layer 772. White light emission can be obtained when the light-emitting layer 771 and the light-emitting layer 772 emit light of complementary colors. FIG. 27F illustrates an example in which the layer 764 is further provided. One or both of a color conversion layer and a color filter (coloring layer) can be used as the layer 764. When white light passes through the coloring filter, light of a desired color can be obtained.

Although FIG. 27E and FIG. 27F illustrate examples where the light-emitting unit 763a includes one the light-emitting layer 771 and the light-emitting unit 763b includes one the light-emitting layer 772, one embodiment of the present invention is not limited thereto. Each of the light-emitting unit 763a and the light-emitting unit 763b may include two or more light-emitting layers.

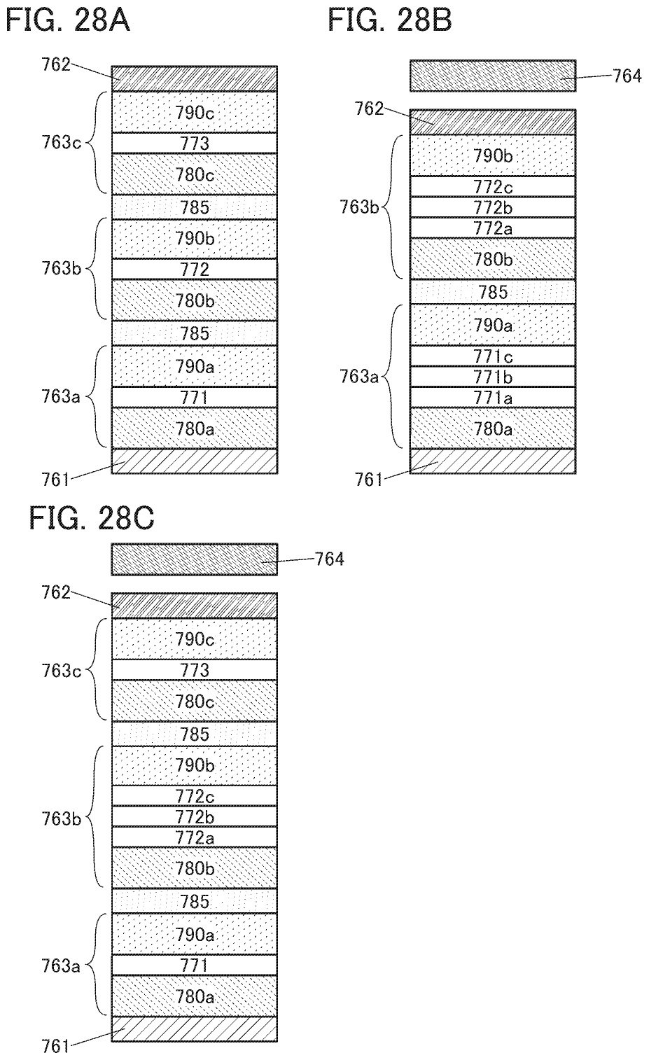

Although FIG. 27E and FIG. 27F illustrate the light-emitting device including two light-emitting units, one embodiment of the present invention is not limited thereto. The light-emitting device may include three or more light-emitting units. Specifically, the light-emitting device may have any of structures illustrated in FIG. 28A to FIG. 28C.

FIG. 28A illustrates a structure including three light-emitting units. Note that a structure including two light-emitting units and a structure including three light-emitting units may be referred to as a two-unit tandem structure and a three-unit tandem structure, respectively.

As illustrated in FIG. 28A, a plurality of light-emitting units (the light-emitting unit 763a, the light-emitting unit 763b, and a light-emitting unit 763c) are connected in series through the charge-generation layers 785. The light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

Note that in the structure illustrated in FIG. 28A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (a so-called R\R\R three-unit tandem structure); the light-emitting layer 771, the light-emitting layer 772, and the light-emitting layer 773 can each contain a light-emitting substance that emits green (G) light (a so-called a G\G\G three-unit tandem structure); or the light-emitting layer 771, the light-emitting layer 772, and the light-emitting layer 773 can each contain a light-emitting substance that emits blue (B) light (a so-called B\B\B three-unit tandem structure).

Note that the structure containing the light-emitting substances that emit light of the same color is not limited to the above structure. For example, a light-emitting device with a tandem structure may be employed in which light-emitting units each including a plurality of light-emitting substances are stacked as illustrated in FIG. 28B. FIG. 28B illustrates a structure in which a plurality of light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 28B, light-emitting substances for the light-emitting layer 771a, the light-emitting layer 771b, and the light-emitting layer 771c are selected so as to emit light of complementary colors for white (W) light emission. Furthermore, light-emitting substances for the light-emitting layer 772a, the light-emitting layer 772b, and the light-emitting layer 772c are selected so as to emit light of complementary colors for white (W) light emission. That is, the structure illustrated in FIG. 28C is a two-unit tandem structure of WWW. Note that there is no particular limitation on the stacking order of the light-emitting substances emitting light of complementary colors for the light-emitting layer 771a, the light-emitting layer 771b, and the light-emitting layer 771c. The practitioner can select the optimal stacking order as appropriate. Although not illustrated, a three-unit tandem structure of W\W\W or a tandem structure with four or more units may be employed.

In the case where a light-emitting device with a tandem structure is used, the following structures can be given: a BY two-unit tandem structure including a light-emitting unit that emits yellow (Y) light and a light-emitting unit that emits blue (B) light; an R·G\B two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order.

As illustrated in FIG. 28C, a light-emitting unit including one light-emitting substance and a light-emitting unit including a plurality of light-emitting substances may be used in combination.

Specifically, in the structure illustrated in FIG. 28C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 28C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Also in FIG. 27C and FIG. 27D, the layer 780 and the layer 790 may each independently have a stacked-layer structure of two or more layers as illustrated in FIG. 27B.

In FIG. 27E and FIG. 27F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 771 and the hole-transport layer.

In the case of manufacturing a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

Next, materials that can be used for the light-emitting device will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display device includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used as the electrode through which light is not extracted. In that case, a conductive film that transmits visible light is preferably provided between the conductive film that reflects visible light and the EL layer 763. In other words, light emitted from the EL layer 763 may be reflected by the reflective film that reflects visible light and extracted from the display device.

As a material that forms the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Examples of the material include indium tin oxide (In—Sn oxide, also referred to as ITO), In—Si—Sn oxide (also referred to as ITSO), indium zinc oxide (In—Zn oxide), and In—W—Zn oxide. Examples of the material include an alloy containing aluminum (aluminum alloy) such as an alloy of aluminum, nickel, and lanthanum (Al—Ni—La), and an alloy of silver, palladium, and copper (Ag—Pd—Cu, also referred to as APC). Other example of the material include elements belonging to Group 1 and Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Thus, one of the pair of electrodes of the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer having a property of reflecting visible light and a conductive layer having a property of transmitting visible light. The visible light transmittance of the conductive layer having a transmitting property is higher than or equal to 40%. For example, an electrode having a visible light (light with a wavelength greater than or equal to 400 nm and less than 750 nm) transmittance higher than or equal to 40% is preferably used in the light-emitting device. The transflective electrode has a visible light reflectance higher than or equal to 10% and lower than or equal to 95%, preferably higher than or equal to 30% and lower than or equal to 80%. The conductive layer having a property of reflecting visible light has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting device includes at least the light-emitting layer. The light-emitting device may further include, as a layer other than the light-emitting layer, a layer containing a material with a high hole-injection property, a material with a high hole-transport property, a hole-blocking material, a material with a high electron-transport property, an electron-blocking material, a material with a high electron-injection property, a material with a bipolar property (a material with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be contained. Each layer included in the light-emitting device can be formed by any of the following methods: an evaporation method (including a vacuum evaporation method), a transfer method, a printing method, an ink-jet method, a coating method, and the like.

The light-emitting layer contains one or more kinds of light-emitting substances. As the light-emitting substance, a substance exhibiting an emission color of blue, violet, bluish violet, green, yellowish green, yellow, orange, red, or the like is used as appropriate. Alternatively, as the light-emitting substance, a substance emitting near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a material with a high hole-transport property (a hole-transport material) and a material with a high electron-transport property (an electron-transport material) can be used. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

In addition to the light-emitting layer, the EL layer 763 may further include a layer containing any of a material having a high hole-injection property, a material having a high hole-transport property, a hole-blocking material, a material having a high electron-transport property, a material having a high electron-injection property, an electron-blocking material, a material having a bipolar property (a material having a high electron-transport property and a high hole-transport property), and the like.

The hole-injection layer injects holes from the anode to the hole-transport layer and contains a material with a high hole-injection property. Examples of a material with a high hole-injection property include an aromatic amine compound and a composite material containing a hole-transport material and an acceptor material (electron-accepting material).

As the hole-transport material, it is possible to use a material having a high hole-transport property which can be used for the hole-transport layer and will be described later.

As the acceptor material, an oxide of a metal belonging to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can be used. An organic acceptor material such as a quinodimethane derivative, a chloranil derivative, or a hexaazatriphenylene derivative can be used.

For example, a hole-transport material and a material containing an oxide of a metal belonging to Group 4 to Group 8 of the periodic table (typically, molybdenum oxide) may be used as the material having a high hole-injection property.

The hole-transport layer transports holes injected from the anode by the hole-injection layer, to the light-emitting layer. The hole-transport layer contains a hole-transport material. As the hole-transport material, a material having a hole mobility higher than or equal to 1× 10⁻⁶ cm²/Vs is preferable. Note that other materials can also be used as long as the materials have a hole-transport property higher than an electron-transport property. As the hole-transport material, a material with a high hole-transport property, such as a n-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer transports electrons injected from the cathode by the electron-injection layer, to the light-emitting layer. The electron-transport layer contains an electron-transport material. As the electron-transport material, a substance having an electron mobility higher than or equal to 1×10⁻⁶ cm²/Vs is preferable. Note that other materials can also be used as long as the materials have an electron-transport property higher than a hole-transport property. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a x-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The difference between the LUMO level of the material with a high electron-injection property and the work function value of the material used for the cathode is preferably small (specifically, smaller than or equal to 0.5 eV).

The electron-injection layer can be formed using, for example, an alkali metal, an alkaline earth metal, or a compound thereof, such as lithium, cesium, ytterbium, lithium fluoride (LiF), cesium fluoride (CsF), calcium fluoride (CaF., where X is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOₓ), or cesium carbonate. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, or a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di (naphthalen-2-yl)-4,7-diphenyl-1,10-phenanthroline (abbreviation: NBPhen), diquinoxalino [2,3-a:2′,3′-c] phenazine (abbreviation: HATNA), 2,4,6-tris [3′-(pyridin-3-yl) biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

In the case of manufacturing a tandem light-emitting device, a charge-generation layer (also referred to as an intermediate layer) is provided between two light-emitting units. The charge-generation layer has a function of injecting electrons into one of the two light-emitting units and injecting holes into the other when voltage is applied between the pair of electrodes. The charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (lithium oxide (Li₂O) or the like). Alternatively, a material that can be used for the electron-injection layer can be suitably used for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, the characteristics, or the like.

The charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

This embodiment can be combined with the other embodiments as appropriate.

### Embodiment 5

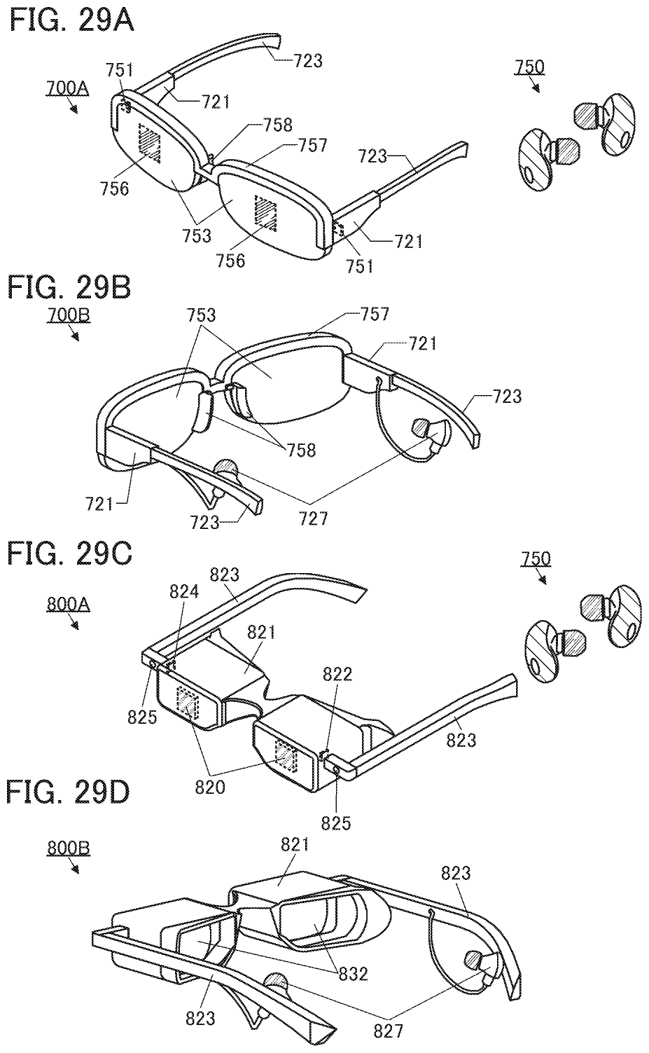

In this embodiment, electronic devices of one embodiment of the present invention are described with reference to FIG. 29 to FIG. 31.

An electronic device of this embodiment is provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or laptop personal computer, a monitor of a computer or the like, digital signage, and a large game machine like a pachinko machine.

In particular, the display device of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head mounted display, a glasses-type device for AR, and a device for MR.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display device of one embodiment of the present invention is preferably higher than or equal to 100 ppi, higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display device with one or both of high definition and high resolution, the electronic device can have higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices are described with reference to FIG. 29A to FIG. 29D. These wearable devices have at least one of a function of displaying AR contents, a function of displaying VR contents, a function of displaying SR contents, and a function of displaying MR contents. The electronic device having a function of displaying a content of at least one of AR, VR, SR, MR, and the like enables the user to reach a higher level of immersion.

An electronic device 700A illustrated in FIG. 29A and an electronic device 700B illustrated in FIG. 29B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panel 751. Thus, the electronic device can perform display with extremely high resolution.

The electronic device 700A and the electronic device 700B can each project an image displayed on the display panel 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display region 756.

The communication portion includes a wireless communication device, and a video signal and the like can be supplied by the wireless communication device. Note that instead of or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two the housings 721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 29C and an electronic device 800B illustrated in FIG. 29D each include a pair of display portions 820, a housing 821, a communication portion 822, a pair of wearing portions 823, a control portion 824, a pair of image capturing portions 825, and a pair of lenses 832.

A display device of one embodiment of the present invention can be used in the display portions 820. Thus, the electronic device can perform display with extremely high resolution. This enables a user to feel high sense of immersion.

The display portions 820 are positioned inside the housing 821 so as to be seen through the lenses 832. When the pair of the display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 29C or the like illustrates an example in which the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is described here, a range sensor capable of measuring a distance between the user and an object (hereinafter also referred to as a sensing portion) just needs to be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 29A has a function of transmitting information to the earphones 750 with the wireless communication function. As another example, the electronic device 800A illustrated in FIG. 29C has a function of transmitting information to the earphones 750 with the wireless communication function.

The electronic device may include an earphone portion. The electronic device 700B illustrated in FIG. 29B includes earphone portions 727. For example, a structure in which the earphone portions 727 and the control portion are connected to each other by wire may be employed. Part of a wiring that connects the earphone portions 727 and the control portion may be positioned inside the housing 721 or the wearing portion 723.

Similarly, the electronic device 800B illustrated in FIG. 29D includes earphone portions 827. For example, a structure in which the earphone portions 827 and the control portion 824 are connected to each other by wire may be employed. Part of a wiring that connects the earphone portions 827 and the control portion 824 may be positioned inside the housing 821 or the wearing portion 823. The earphone portions 827 and the wearing portion 823 may include magnets. This is preferable because the earphone portions 827 can be fixed to the wearing portion 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

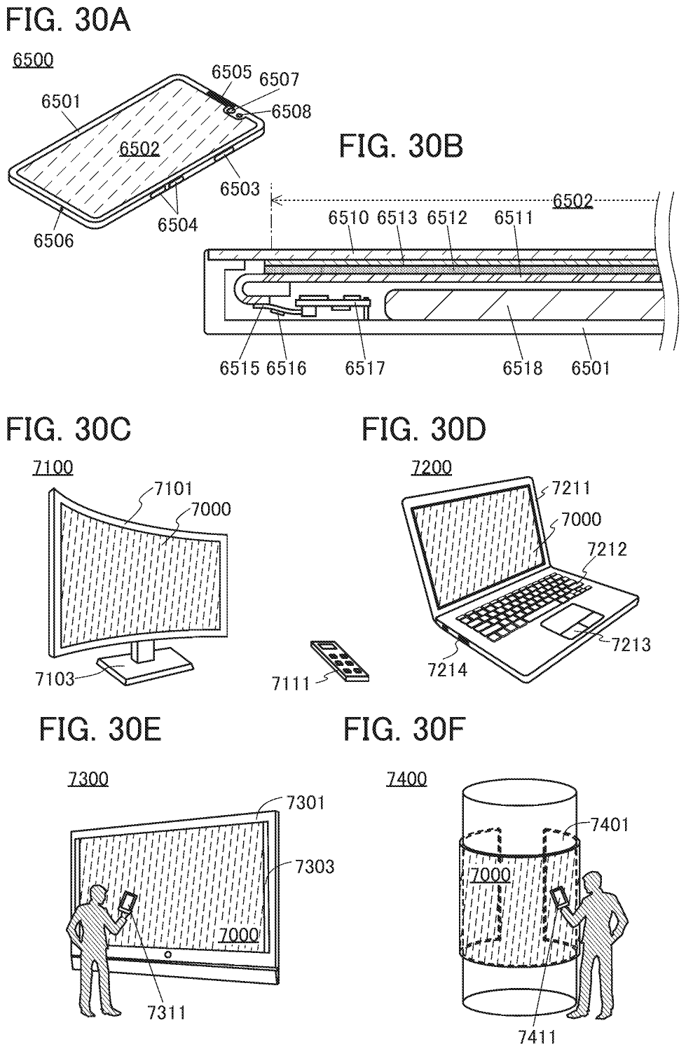

An electronic device 6500 illustrated in FIG. 30A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 30B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be achieved.

FIG. 30C illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 30C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 30D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated. The display device of one embodiment of the present invention can be used for the display portion 7000.

FIG. 30E and FIG. 30F illustrate examples of digital signage.

Digital signage 7300 illustrated in FIG. 30E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 30F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 30E and FIG. 30F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 30E and FIG. 30F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

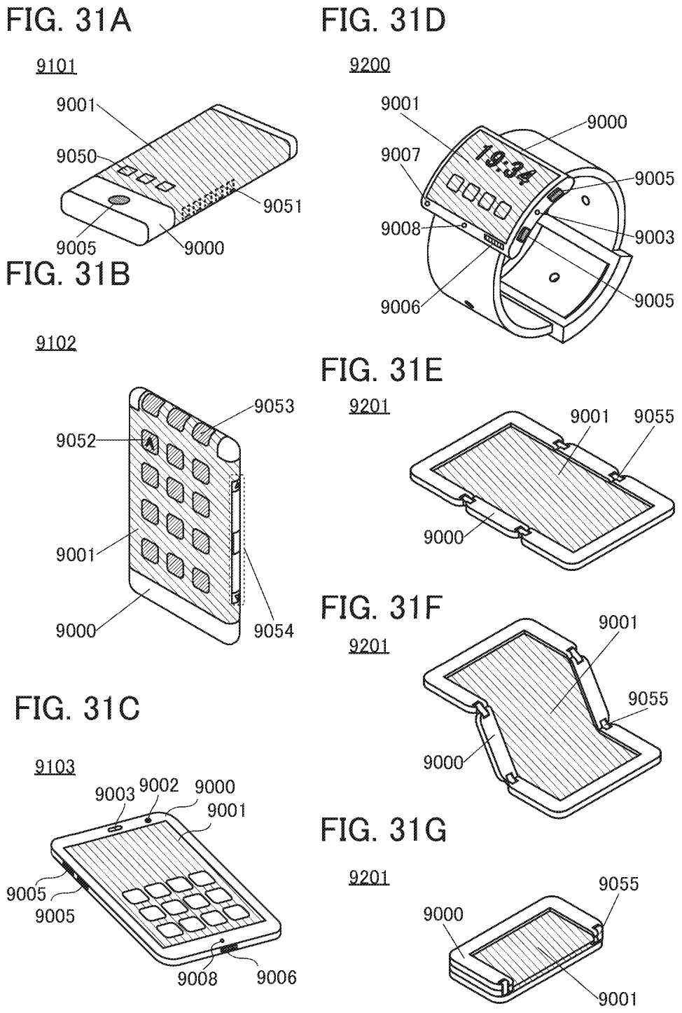

Electronic devices illustrated in FIG. 31A to FIG. 31G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 31A to FIG. 31G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 31A to FIG. 31G are described in detail below.

FIG. 31A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 31A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 31B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 31C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 31D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 31E to FIG. 31G are perspective views illustrating a foldable portable information terminal 9201. FIG. 31E is a perspective view of an opened state of the portable information terminal 9201, FIG. 31G is a perspective view of a folded state thereof, and FIG. 31F is a perspective view of a state in the middle of change from one of FIG. 31E and FIG. 31G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined with the other embodiments as appropriate.

### REFERENCE NUMERALS

100A: display device, 100B: display device, 100C: display device, 100D: display device, 100E: display device, 100F: display device, 100G: display device, 100H: display device, 100: display device, 101: layer, 110a: subpixel, 110B: subpixel, 110b: subpixel, 110c: subpixel, 110d: subpixel, 110e: subpixel, 110G: subpixel, 110R: subpixel, 110: pixel, 111a: pixel electrode, 111b: pixel electrode, 111c: pixel electrode, 111: pixel electrode, 112a: conductive layer, 112b: conductive layer, 112c: conductive layer, 113: EL layer, 114: common layer, 115: common electrode, 116a: conductive layer, 116aA: conductive layer, 116aB: conductive layer, 116aC: conductive layer, 116b: conductive layer, 116bA: conductive layer, 116bB: conductive layer, 116c: conductive layer, 116fA: conductive film, 116fB: conductive film, 116fC: conductive film, 116p: conductive layer, 116q: conductive layer, 116: conductive layer, 117: light-blocking layer, 119: organic layer, 120: substrate, 122: resin layer, 123: conductive layer, 124a: pixel, 124b: pixel, 126a: conductive layer, 126b: conductive layer, 126c: conductive layer, 128: layer, 130a: light-emitting device, 130B: light-emitting device, 130b: light-emitting device, 130c: light-emitting device, 130G: light-emitting device, 130R: light-emitting device, 130: light-emitting device, 131: protective layer, 132B: coloring layer, 132G: coloring layer, 132R: coloring layer, 132: coloring layer, 133: lens array, 134: insulating layer, 140: connection portion, 142: adhesive layer, 151: substrate, 152: substrate, 153: insulating layer, 162: display portion, 164: circuit, 165: wiring, 166: conductive layer, 168: insulating layer, 172: FPC, 173: IC, 181A: insulating layer, 181f: insulating film, 181: insulating layer, 183: gap, 187: opening, 190A: resist mask, 190Ba: resist mask, 190Bb: resist mask, 190Ca: resist mask, 190Cb: resist mask, 190Cc: resist mask, 190Cp: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 23 In: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first light-emitting device;
a second light-emitting device; and
an insulating layer,
wherein the first light-emitting device comprises a first pixel electrode, a first EL layer over the first pixel electrode, and a common electrode over the first EL layer,
wherein the second light-emitting device comprises a second pixel electrode, a second EL layer over the second pixel electrode, and the common electrode over the second EL layer,
wherein the insulating layer comprises an opening,
wherein the insulating layer comprises a first surface in contact with a side surface of the first pixel electrode, a second surface facing the first surface, a third surface in contact with a bottom surface of the first EL layer, a fourth surface in contact with a side surface of the second pixel electrode, a fifth surface facing the fourth surface, and a sixth surface in contact with a bottom surface of the second EL layer,
wherein the insulating layer comprises a region where the third surface, the sixth surface, a top surface of the first pixel electrode, and a top surface of the second pixel electrode are level or substantially level with each other,
wherein an angle formed between the second surface and the third surface is greater than or equal to 80° and less than or equal to 110° in a cross-sectional view,
wherein the first EL layer contains the same material as the second EL layer, and
wherein the first EL layer is separated from the second EL layer.

2. The display device according to claim 1,
wherein a ratio of a depth of the opening to a thickness of the first EL layer is higher than or equal to 0.5 and lower than or equal to 10.0.

3. The display device according to claim 1,
wherein a width of the opening is greater than or equal to 50 nm and less than or equal to 500 nm.

4. The display device according to claim 1,
wherein a ratio of a depth of the opening to a thickness of the first EL layer is higher than or equal to 0.5 and lower than or equal to 10.0, and
wherein a width of the opening is greater than or equal to 50 nm and less than or equal to 500 nm.

5. The display device according to claim 1, further comprising:
a first coloring layer; and
a second coloring layer,
wherein the first coloring layer comprises a region overlapping with the first light-emitting device,
wherein the second coloring layer comprises a region overlapping with the second light-emitting device, and
wherein a wavelength of light transmitted through the second coloring layer is shorter than a wavelength of light transmitted through the first coloring layer.

6. The display device according to claim 1 comprising:
a first conductive layer; and
a second conductive layer,
wherein the first conductive layer and the second conductive layer each transmit visible light,
wherein the first conductive layer is interposed between the first pixel electrode and the first EL layer,
wherein the second conductive layer is interposed between the second pixel electrode and the second EL layer, and
wherein a thickness of the second conductive layer is smaller than a thickness of the first conductive layer.

7. The display device according to claim 5 comprising:
a first conductive layer; and
a second conductive layer,
wherein the first conductive layer and the second conductive layer each transmit visible light,
wherein the first conductive layer is interposed between the first pixel electrode and the first EL layer,
wherein the second conductive layer is interposed between the second pixel electrode and the second EL layer, and
wherein a thickness of the second conductive layer is smaller than a thickness of the first conductive layer.

8. The display device according to claim 6,
wherein a side surface of the first conductive layer is aligned or substantially aligned with the second surface, and
wherein a side surface of the second conductive layer is aligned or substantially aligned with the fifth surface.

9. The display device according to claim 7,
wherein a side surface of the first conductive layer is aligned or substantially aligned with the second surface, and
wherein a side surface of the second conductive layer is aligned or substantially aligned with the fifth surface.

10. A method for manufacturing a display device, comprising the steps of:
forming a first pixel electrode and a second pixel electrode;
forming an insulating film covering top surfaces and side surfaces of the first pixel electrode and the second pixel electrode;
removing part of the insulating film, thereby forming an insulating layer having a top surface at a same level or substantially a same level with the top surface of the first pixel electrode and the top surface of the second pixel electrode;
forming an opening in the insulating layer;
forming a first EL layer over the first pixel electrode and forming a second EL layer which is separated from the first EL layer over the second pixel electrode; and
forming a common electrode over the first EL layer and over the second EL layer;
wherein the insulating layer comprises a first surface in contact with the side surface of the first pixel electrode, a second surface facing the first surface, and a third surface in contact with a bottom surface of the first EL layer,
wherein the insulating layer comprises a region where the third surface is level or substantially level with the top surface of the first pixel electrode,
wherein an angle formed between the second surface and the third surface is greater than or equal to 80° and less than or equal to 110° in a cross-sectional view, and
wherein the first EL layer contains the same material as the second EL layer.
